(19) United States
(12) Patent Application Publication
(10) Pub. No.: US 2025/0098231 A1
(43) Pub. Date: Mar. 20, 2025

(54) SEMICONDUCTOR DEVICE MANUFACTURING METHOD AND SEMICONDUCTOR DEVICE

(71) Applicant: KABUSHIKI KAISHA TOSHIBA, Tokyo (JP)

(72) Inventor: Tatsuo SHIMIZU, Shinagawa Tokyo (JP)

(73) Assignee: KABUSHIKI KAISHA TOSHIBA, Tokyo (JP)

(21) Appl. No.: 18/594,219

(22) Filed: Mar. 4, 2024

(30) Foreign Application Priority Data
Sep. 14, 2023 (JP) 2023-148888
Feb. 26, 2024 (JP) 2024-026554

(51) Int. Cl. H01L 29/06; H01L 21/324; H01L 29/16; H01L 29/66; H01L 29/78

(52) U.S. Cl. CPC H10D 62/10; H01L 21/324; H10D 30/0297; H10D 30/668; H10D 62/8325

(57) ABSTRACT

A semiconductor device manufacturing method of embodiments includes: forming a trench in a silicon carbide layer having a surface inclined by an angle equal to or more than 0 degrees and equal to or less than 8 degrees with respect to a {0001}face; forming a silicon oxide film on an inner surface of the trench, the atomic concentration of oxygen (O) in the silicon oxide film being less than twice the atomic concentration of silicon (Si) in the silicon oxide film; performing a first heat treatment in an atmosphere containing nitrogen oxide gas after forming the silicon oxide film; performing a second heat treatment in an atmosphere containing at least one element selected from a group consisting of hydrogen (H), deuterium (D), and fluorine (F) after the first heat treatment; and forming a gate electrode on the silicon oxide film after the second heat treatment.

### CROSS-REFERENCE TO RELATED APPLICATION

This application is based upon and claims the benefit of priority from Japanese Patent Applications No. 2023-148888, filed on Sep. 14, 2023, and No. 2024-26554, filed on Feb. 26, 2024, the entire contents of which are incorporated herein by reference.

### FIELD

Embodiments described herein relate generally to a semiconductor device manufacturing method and a semiconductor device.

### BACKGROUND

Silicon carbide (SiC) is expected as a material for next-generation semiconductor devices. Silicon carbide has excellent physical properties, such as a bandgap of 3 times, a breakdown field strength of about 10 times, and a thermal conductivity of about 3 times that of silicon (Si). By using these physical properties, it is possible to realize a semiconductor device that can operate at high temperature with low loss.

For example, when a metal oxide semiconductor field effect transistor (MOSFET) is formed using silicon carbide, there is a problem that the mobility of carriers decreases or the threshold voltage fluctuates. One of the factors that cause a decrease in carrier mobility or a fluctuation in threshold voltage is thought to be defects such as nitrogen defects or carbon defects in the gate insulating layer.

### BRIEF DESCRIPTION OF THE DRAWINGS

FIG. 1 is a schematic cross-sectional view of a semiconductor device according to a first embodiment;

FIG. 2 is a diagram showing the crystal structure of a SiC semiconductor;

FIG. 3 is a diagram showing an example of the element concentration distribution of the semiconductor device according to the first embodiment;

FIG. 4 is a process flow diagram of a semiconductor device manufacturing method according to the first embodiment;

FIG. 5 is an explanatory diagram of an example of defects in a gate insulating layer;

FIG. 6 is a schematic cross-sectional view of a semiconductor device according to a second embodiment;

FIG. 7 is a diagram showing an example of the element concentration distribution of the semiconductor device according to the second embodiment;

FIG. 8 is a process flow diagram of a semiconductor device manufacturing method according to the second embodiment;

FIG. 9 is a schematic cross-sectional view illustrating the semiconductor device manufacturing method according to the second embodiment;

FIG. 10 is a schematic cross-sectional view illustrating the semiconductor device manufacturing method according to the second embodiment;

FIG. 11 is a schematic cross-sectional view illustrating the semiconductor device manufacturing method according to the second embodiment;

FIG. 12 is a schematic cross-sectional view illustrating the semiconductor device manufacturing method according to the second embodiment;

FIG. 13 is a schematic cross-sectional view illustrating the semiconductor device manufacturing method according to the second embodiment;

FIG. 14 is a schematic cross-sectional view illustrating the semiconductor device manufacturing method according to the second embodiment;

FIG. 15 is a schematic cross-sectional view of a semiconductor device according to a third embodiment;

FIG. 16 is a diagram showing an example of the element concentration distribution of the semiconductor device according to the third embodiment; and

FIG. 17 is a process flow diagram of a semiconductor device manufacturing method according to the third embodiment.

### DETAILED DESCRIPTION

A semiconductor device manufacturing method of embodiments includes: forming a trench in a silicon carbide layer having a surface inclined by an angle equal to or more than 0 degrees and equal to or less than 8 degrees with respect to a {0001}face; forming a silicon oxide film on an inner surface of the trench, an atomic concentration of oxygen (O) in the silicon oxide film being less than twice an atomic concentration of silicon (Si) in the silicon oxide film; performing a first heat treatment in an atmosphere containing nitrogen oxide gas after forming the silicon oxide film; performing a second heat treatment in an atmosphere containing at least one element selected from a group consisting of hydrogen (H), deuterium (D), and fluorine (F) after the first heat treatment; and forming a gate electrode on the silicon oxide film after the second heat treatment.

Hereinafter, embodiments will be described with reference to the diagrams. In addition, in the following description, the same or similar members and the like are denoted by the same reference numerals, and the description of the members and the like once described will be omitted as appropriate.

In addition, in the following description, when there are notations of n⁺, n, n⁻, p⁺, p, and p⁻, these indicate the relative high and low of the impurity concentration in each conductive type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type. Unless otherwise specified, the impurity concentration in each region is represented by, for example, the value of the impurity concentration in the central portion of each region.

The impurity concentration can be measured by, for example, secondary ion mass spectrometry (SIMS). In addition, the relative high and low of the impurity concentration can also be determined from, for example, the high and low of the carrier concentration obtained by scanning capacitance microscopy (SCM). In addition, the distance such as the width or depth of an impurity region can be calculated by, for example, SIMS. In addition, the distance such as the width or depth of an impurity region can be calculated from, for example, an SCM image.

The depth of a trench, the thickness of an insulating layer, and the like can be measured, for example, on an image of SIMS or transmission electron microscope (TEM).

The bonding states of silicon atoms, carbon atoms, nitrogen atoms, and oxygen atoms in the silicon carbide layer can be identified by using, for example, X-ray photoelectron spectroscopy (XPS method). In addition, the concentrations of various bonding states and the magnitude relationship between the concentrations can be determined by using, for example, X-ray photoelectron spectroscopy (XPS method).

### First Embodiment

A semiconductor device manufacturing method according to a first embodiment includes: forming a trench in a silicon carbide layer having a surface inclined by an angle equal to or more than 0 degrees and equal to or less than 8 degrees with respect to a {0001}face; forming a silicon oxide film on an inner surface of the trench, an atomic concentration of oxygen (O) in the silicon oxide film being less than twice an atomic concentration of silicon (Si) in the silicon oxide film; performing a first heat treatment in an atmosphere containing nitrogen oxide gas after forming the silicon oxide film; performing a second heat treatment in an atmosphere containing at least one element selected from a group consisting of hydrogen (H), deuterium (D), and fluorine (F) after the first heat treatment; and forming a gate electrode on the silicon oxide film after the second heat treatment.

A semiconductor device according to the first embodiment includes: a silicon carbide layer having a surface inclined by an angle equal to or more than 0 degrees and equal to or less than 8 degrees with respect to a {0001}face and including a trench; a gate electrode provided in the trench; a silicon oxide layer provided between the silicon carbide layer and the gate electrode; and a region provided between the silicon carbide layer and the silicon oxide layer and containing nitrogen (N) and at least one element selected from a group consisting of hydrogen (H), deuterium (D), and fluorine (F). The semiconductor device according to the first embodiment is manufactured by using, for example, the semiconductor device manufacturing method according to the first embodiment.

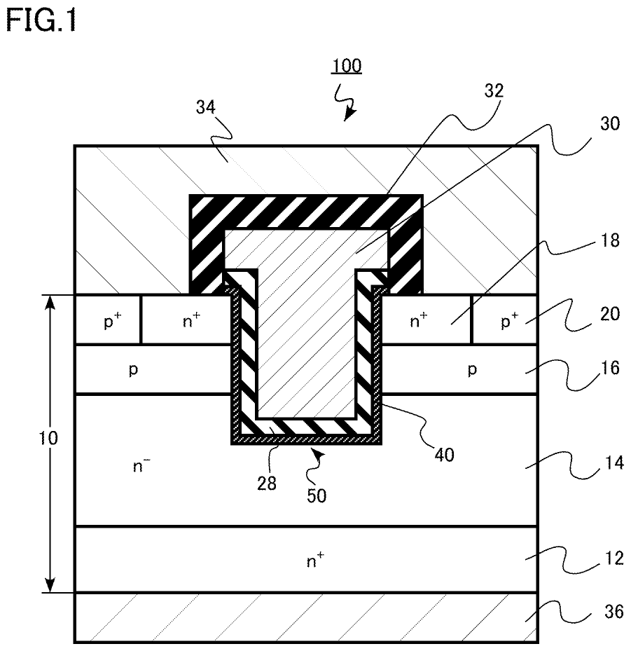

FIG. 1 is a schematic cross-sectional view of the semiconductor device according to the first embodiment. The semiconductor device is a MOSFET 100. The MOSFET 100 is a trench gate type MOSFET having a gate electrode in a trench. In addition, the MOSFET 100 is an n-channel MOSFET having electrons as carriers.

The MOSFET 100 includes a silicon carbide layer 10, a gate insulating layer 28 (silicon oxide layer), a gate electrode 30, an interlayer insulating film 32, a source electrode 34, a drain electrode 36, and an interface termination region 40 (region).

The silicon carbide layer 10 includes a drain region 12, a drift region 14, a p-well region 16, a source region 18, a p-well contact region 20, and a trench 50.

The silicon carbide layer 10 is, for example, a single crystal of 4H—SiC. The silicon carbide layer 10 is disposed between the source electrode 34 and the drain electrode 36.

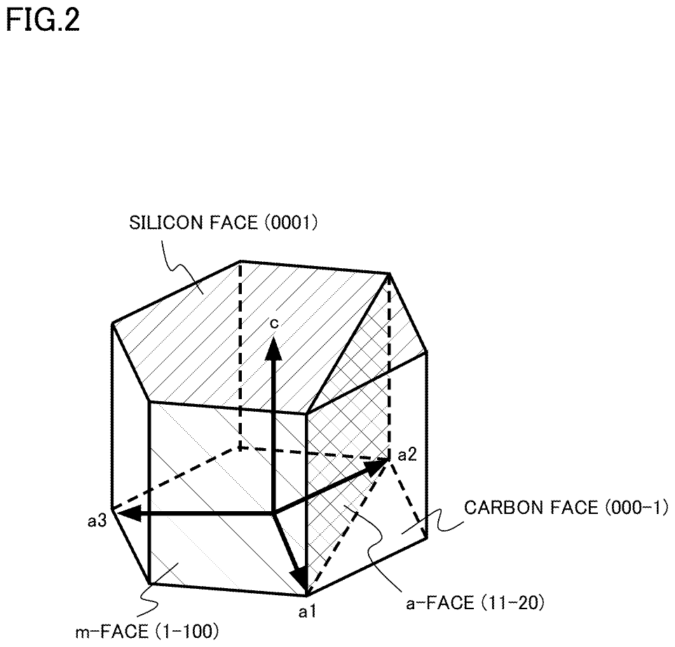

FIG. 2 is a diagram showing the crystal structure of a SiC semiconductor. A typical crystal structure of a SiC semiconductor is a hexagonal system such as 4H—SiC. One of the faces (top surface of the hexagonal column) whose normal line is a c-axis along the axial direction of the hexagonal column is a (0001) face. The face equivalent to the (0001) face is referred to as a silicon face (Si face) and denoted as a {0001}face. Silicon atoms (Si) are arranged on the outermost surface of the silicon face.

The other side of the face (top surface of the hexagonal column) whose normal line is the c-axis along the axial direction of the hexagonal column is a (000-1) face. The face equivalent to the (000-1) face is referred to as a carbon face (C face) and denoted as a {000-1}face. Carbon atoms (C) are arranged on the outermost surface of the carbon face.

On the other hand, the side surface (pillar surface) of the hexagonal column is an m-face that is a face equivalent to the (1-100) face, that is, a {1-100}face. In addition, the face passing through a pair of non− adjacent ridge lines is an a-face that is a face equivalent to the (11-20) face, that is, a {11-20}face. Both silicon atoms (Si) and carbon atoms (C) are arranged on the outermost surfaces of the m-face and the a-face.

The surface of the silicon carbide layer 10 is a face inclined by an angle equal to or more than 0 degrees and equal to or less than 8 degrees with respect to the silicon face and the back surface of the silicon carbide layer 10 is a face inclined by an angle equal to or more than 0 degrees and equal to or less than 8 degrees with respect to the carbon face will. The surface of the silicon carbide layer 10 has an off angle equal to or more than 0 degrees and equal to or less than 8 degrees with respect to the silicon face.

The drain region 12 is an n⁺-type SiC. The drain region 12 contains, for example, nitrogen (N) as an n-type impurity. The n-type impurity concentration in the drain region 12 is, for example, equal to or more than 1×10¹⁸ cm⁻³ and equal to or less than 1×10²¹ cm⁻³.

The drift region 14 is provided on the drain region 12. The drift region 14 is an n⁻-type SiC. The drift region 14 contains, for example, nitrogen as an n-type impurity.

The n-type impurity concentration in the drift region 14 is lower than the n-type impurity concentration in the drain region 12. The n-type impurity concentration in the drift region 14 is, for example, equal to or more than 1×10¹⁵ cm⁻³ and equal to or less than 2×10¹⁶ cm⁻³. The drift region 14 is, for example, a SiC epitaxial growth layer formed on the drain region 12 by epitaxial growth.

The thickness of the drift region 14 is, for example, equal to or more than 5 μm and equal to or less than 100 μm.

The p-well region 16 is provided on a partial surface of the drift region 14. The p-well region 16 is a p-type SiC. The p-well region 16 contains, for example, aluminum (Al) as a p-type impurity. The p-type impurity concentration in the p-well region 16 is, for example, equal to or more than 1×10¹⁶ cm⁻³ and equal to or less than 1×10²⁰ cm⁻³.

The depth of the p-well region 16 is, for example, equal to or more than 0.4 μm and equal to or less than 0.8 μm. The p-well region 16 functions as a channel region of the MOSFET 100.

The source region 18 is provided on a partial surface of the p-well region 16. The source region 18 is an n⁺-type SiC. The source region 18 contains, for example, phosphorus (P) as an n-type impurity. The n-type impurity concentration in the source region 18 is, for example, equal to or more than 1×10¹⁸ cm⁻³ and equal to or less than 1×10²² cm⁻³.

The depth of the source region 18 is smaller than the depth of the p-well region 16. The depth of the source region 18 is, for example, equal to or more than 0.2 μm and equal to or less than 0.4 μm.

The p-well contact region 20 is provided on a partial surface of the p-well region 16. The p-well contact region 20 is provided on the side of the source region 18. The p-well contact region 20 is a p⁺-type SiC.

The p-well contact region 20 contains, for example, aluminum as a p-type impurity. The p-type impurity concentration in the p-well contact region 20 is, for example, equal to or more than 1×10¹⁸ cm⁻³ and equal to or less than 1×10²² cm⁻³.

The depth of the p-well contact region 20 is smaller than the depth of the p-well region 16. The depth of the p-well contact region 20 is, for example, equal to or more than 0.2 μm and equal to or less than 0.4 μm.

The trench 50 passes through the source region 18 and the p-well region 16 and reaches the drift region 14. The bottom surface of the trench 50 is disposed in the drift region 14. The trench 50 is a groove provided in the silicon carbide layer 10.

The face orientation of the inner surface of the trench 50 is, for example, a face inclined by an angle equal to or more than 0 degrees and equal to or less than 8 degrees with respect to the m-face. In other words, the face orientation of the inner surface of the trench 50 is, for example, a face inclined by an angle equal to or more than 0 degrees and equal to or less than 8 degrees with respect to the {1-100}face.

The face orientation of the inner surface of the trench 50 is, for example, a face inclined by an angle equal to or more than 0 degrees and equal to or less than 8 degrees with respect to the a-face. In other words, the face orientation of the inner surface of the trench 50 is, for example, a face inclined by an angle equal to or more than 0 degrees and equal to or less than 8 degrees with respect to the {11-20}face.

The gate insulating layer 28 is provided in the trench 50. The gate insulating layer 28 is provided between the silicon carbide layer 10 and the gate electrode 30. The gate insulating layer 28 is provided between the drift region 14 and the p-well region 16 and the gate electrode 30. The gate insulating layer 28 is provided above the drift region 14 and the p-well region 16. The gate insulating layer 28 is continuously formed on the surfaces of the drift region 14 and the p-well region 16.

The gate insulating layer 28 is a silicon oxide.

The thickness of the gate insulating layer 28 is, for example, equal to or more than 30 nm and equal to or less than 100 nm. The gate insulating layer 28 functions as a gate insulating layer of the MOSFET 100.

The interface termination region 40 is disposed between the silicon carbide layer 10 and the gate insulating layer 28. The interface termination region 40 is disposed between the drift region 14 and the p-well region 16 and the gate insulating layer 28.

The interface termination region 40 contains nitrogen (N) as a termination element for terminating dangling bonds in the silicon carbide layer 10. Nitrogen (N) terminates dangling bonds of silicon in the silicon carbide layer 10, for example.

In addition, the interface termination region 40 contains at least one element selected from a group consisting of hydrogen (H), deuterium (D), and fluorine (F) as a termination element for terminating dangling bonds in the silicon carbide layer 10. The at least one element described above terminates dangling bonds of carbon in the silicon carbide layer 10, for example.

The atomic concentration of at least one element selected from the group consisting of hydrogen (H), deuterium (D), and fluorine (F) in the interface termination region 40 is lower than the atomic concentration of nitrogen (N) in the interface termination region 40, for example. The atomic concentration of at least one element selected from the group consisting of hydrogen (H), deuterium (D), and fluorine (F) in the interface termination region 40 is, for example, equal to or more than 1/10000 and equal to or less than 1/10 of the atomic concentration of nitrogen (N) in the interface termination region 40.

Hereinafter, a case where the above-described at least one element is hydrogen (H) will be described as an example.

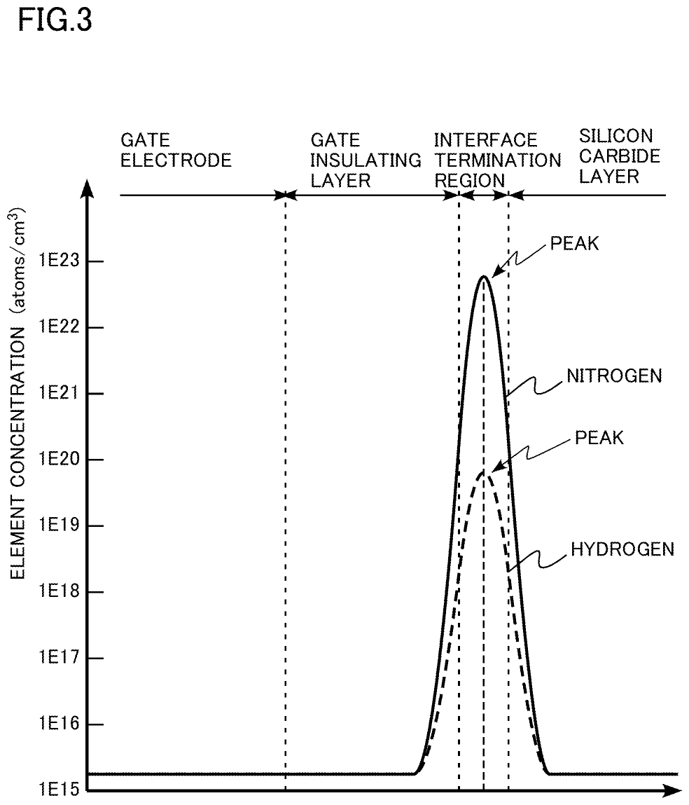

FIG. 3 is a diagram showing an example of the element concentration distribution of the semiconductor device according to the first embodiment. FIG. 3 is a diagram showing the element concentration distribution in the gate electrode 30, the gate insulating layer 28, the interface termination region 40, and the silicon carbide layer 10. FIG. 3 shows the concentration distribution of nitrogen (N) and hydrogen (H).

The concentration distribution of nitrogen (N) has a peak in the interface termination region 40. The atomic concentration of nitrogen at the peak is, for example, equal to or more than 1×10²¹ cm⁻³ and equal to or less than 1×10²³ cm⁻³. The full width at half maximum with respect to the peak of the nitrogen concentration distribution is, for example, equal to or less than 1 nm. Nitrogen is segregated at the interface between the silicon carbide layer 10 and the gate insulating layer 28.

The concentration distribution of hydrogen (H) has a peak in the interface termination region 40. The atomic concentration of hydrogen at the peak is, for example, equal to or more than 1×10¹⁷ cm⁻³ and equal to or less than 1×10²¹ cm⁻³. The full width at half maximum with respect to the peak of the hydrogen concentration distribution is, for example, equal to or less than 1 nm. Hydrogen is segregated at the interface between the silicon carbide layer 10 and the gate insulating layer 28.

Hydrogen terminates dangling bonds of carbon, for example. In the interface termination region 40, the amount of hydrogen bonded to carbon is larger than the amount of hydrogen bonded to silicon. In the interface termination region 40, the concentration of hydrogen bonded to carbon is higher than the concentration of hydrogen bonded to silicon.

The gate electrode 30 is provided in the trench 50. The gate electrode 30 is provided on the gate insulating layer 28. The gate insulating layer 28 is interposed between the gate electrode 30 and the silicon carbide layer 10. The gate insulating layer 28 is interposed between the gate electrode 30 and the drift region 14. The gate insulating layer 28 is interposed between the gate electrode 30 and the p-well region 16.

The gate electrode 30 is, for example, polycrystalline silicon containing n-type impurities or p⁻ type impurities.

The interlayer insulating film 32 is formed on the gate electrode 30. The interlayer insulating film 32 is, for example, a silicon oxide film.

The source electrode 34 is electrically connected to the source region 18 and the p-well contact region 20. The source electrode 34 also functions as a p-well electrode for applying an electric potential to the p-well region 16.

The source electrode 34 has, for example, a stacked structure of a barrier metal layer of nickel (Ni) and a metal layer of aluminum on the barrier metal layer. The barrier metal layer of nickel and the silicon carbide layer may react with each other to form nickel silicide. The nickel silicide is, for example, NiSi or Ni₂Si. The barrier metal layer formed of nickel and the metal layer formed of aluminum may form an alloy by reaction.

The drain electrode 36 is provided on a side of the silicon carbide layer 10 opposite to the source electrode 34, that is, on the back surface side of the silicon carbide layer 10. The drain electrode 36 is, for example, nickel. Nickel may react with the drain region 12 to form nickel silicide. The nickel silicide is, for example, NiSi or Ni₂Si.

In addition, in the MOSFET 100 according to the first embodiment, the n-type impurity is, for example, nitrogen or phosphorus. Arsenic (As) or antimony (Sb) can also be applied as an n-type impurity.

In addition, in the MOSFET 100 according to the first embodiment, the p-type impurity is, for example, aluminum. Boron (B), gallium (Ga), and indium (In) can also be applied as p-type impurities.

Next, an example of the semiconductor device manufacturing method according to the first embodiment will be described.

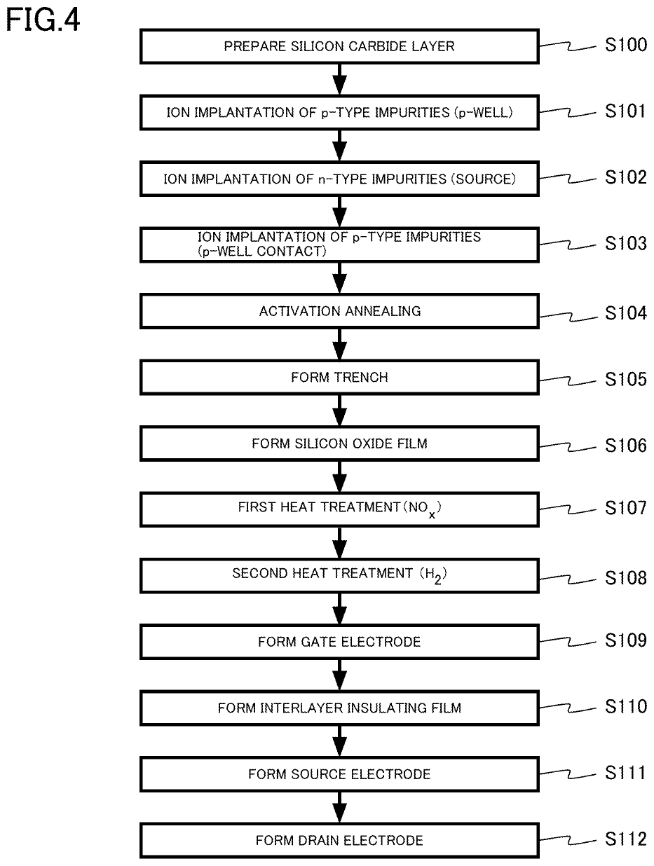

FIG. 4 is a process flow diagram of the semiconductor device manufacturing method according to the first embodiment.

As shown in FIG. 4, the semiconductor device manufacturing method according to the first embodiment includes preparation of a silicon carbide layer (step S100), ion implantation of p-type impurities (step S101), ion implantation of n-type impurities (step S102), ion implantation of p-type impurities (step S103), activation annealing (step S104), formation of a trench (step S105), formation of a silicon oxide film (step S106), first heat treatment (step S107), second heat treatment (step S108), formation of a gate electrode (step S109), formation of an interlayer insulating film (step S110), formation of a source electrode (step S111), and formation of a drain electrode (step S112).

In step S100, silicon carbide layer 10 is prepared. The surface of the silicon carbide layer 10 is a face inclined at an angle equal to or more than 0 degrees and equal to or less than 8 degrees with respect to the {0001}face.

The silicon carbide layer 10 includes an n⁺-type drain region 12 and an n⁻-type drift region 14. The drift region 14 is formed on the drain region 12 by using an epitaxial growth method, for example.

The drain region 12 contains nitrogen as an n-type impurity. The n-type impurity concentration in the drain region 12 is, for example, equal to or more than 1×10¹⁸ cm⁻³ and equal to or less than 1×10²¹ cm⁻³.

The drift region 14 contains nitrogen as an n-type impurity. The n-type impurity concentration in the drift region 14 is, for example, equal to or more than 1×10¹⁵ cm⁻³ and equal to or less than 2×10¹⁶ cm⁻³. The thickness of the drift region 14 is, for example, equal to or more than 5 μm and equal to or less than 100 μm.

In step S101, first, a first mask material is formed by patterning using photolithography and etching. Then, by using the first mask material as an ion implantation mask, aluminum (Al), which is a p-type impurity, is ion-implanted into the drift region 14. By the ion implantation, the p-well region 16 is formed.

In step S102, first, a second mask material is formed by patterning using photolithography and etching. Then, by using the second mask material as an ion implantation mask, phosphorus (P), which is an n-type impurity, is ion-implanted into the drift region 14 to form the source region 18.

In step S103, first, a third mask material is formed by patterning using photolithography and etching. By using the third mask material as an ion implantation mask, aluminum (Al), which is a p-type impurity, is ion-implanted into the drift region 14 to form the p-well contact region 20.

Then, a carbon film is formed on the surface of the silicon carbide layer 10. The carbon film is formed by using, for example, a sputtering method. The carbon film suppresses the surface of the silicon carbide layer 10 from being roughened during the subsequent activation annealing.

In step S104, activation annealing is performed. By the activation annealing, p-type impurities and n-type impurities ion-implanted into the silicon carbide layer 10 are activated. The activation annealing is performed, for example, in an argon atmosphere. The temperature of the activation annealing is, for example, equal to or more than 1600° C. and equal to or less than 1800° C.

Then, the carbon film on the surface of the silicon carbide layer 10 is removed. The carbon film is removed, for example, by an ashing treatment using oxygen plasma.

In step S105, the trench 50 is formed in the silicon carbide layer 10. The trench 50 is formed by using, for example, known photolithography and reactive ion etching methods (RIE method).

In step S106, a silicon oxide film is formed on the surface of the silicon carbide layer 10. The silicon oxide film finally becomes the gate insulating layer 28.

The atomic concentration of oxygen (O) contained in the silicon oxide film is less than twice the atomic concentration of silicon (Si). The silicon oxide film is a silicon-rich silicon oxide film. The silicon oxide film deviates from stoichiometry due to oxygen vacancies to become silicon-rich.

When the chemical composition of the silicon oxide film is expressed as SiO_{2-δ}, for example, 0.01≤δ≤0.1. In other words, the oxygen vacancies in the silicon oxide film are, for example, equal to or more than 0.5% and equal to or less than 5%. In other words, for example, the atomic concentration of oxygen (O) contained in the silicon oxide film is equal to or more than 1.9 times and equal to or less than 1.99 times the atomic concentration of silicon (Si).

The silicon oxide film is formed by using, for example, a vapor deposition method. The silicon oxide film is formed by using, for example, a chemical vapor deposition method (CVD method) or a physical vapor deposition method (PVD method). The silicon oxide film is a deposited film. The thickness of the silicon oxide film is, for example, equal to or more than 30 nm and equal to or less than 100 nm.

The silicon oxide film is, for example, a silicon oxide film formed by a CVD method using tetraethyl orthosilicate (TEOS) as a source gas. In addition, the silicon oxide film is, for example, a silicon oxide film formed by a CVD method using dichlorosilane gas (SiH₂Cl₂) and dinitrogen monoxide gas (N₂O) as source gases.

The silicon oxide film is formed at a temperature equal to or less than 600° C., for example.

For example, by lowering the partial pressure of oxygen in the atmosphere when forming a silicon oxide film, it is possible to form a silicon oxide film that is entirely rich in silicon.

In step S107, a first heat treatment is performed. The first heat treatment is performed in an atmosphere containing nitrogen oxide gas (NOx). The nitrogen oxide gas is, for example, a nitric oxide gas (NO). In addition, the nitrogen oxide gas is, for example, a dinitrogen monoxide gas (N₂O).

For example, the first heat treatment is performed by supplying the nitrogen oxide gas (NOx) to a reactor containing the silicon carbide layer 10.

The temperature of the first heat treatment is, for example, equal to or more than 900° C. and equal to or less than 1250° C.

The partial pressure of the nitrogen oxide gas in the atmosphere of the first heat treatment is, for example, equal to or more than 10%.

By the first heat treatment, the interface termination region 40 is formed. By the first heat treatment, nitrogen is segregated at the interface between the silicon carbide layer 10 and the silicon oxide film. By the first heat treatment, for example, dangling bonds of silicon in the silicon carbide layer 10 are terminated.

In step S108, a second heat treatment is performed. The second heat treatment is performed in an atmosphere containing at least one element selected from the group consisting of hydrogen (H), deuterium (D), and fluorine (F).

The atmosphere of the second heat treatment contains, for example, hydrogen gas, deuterium gas, or fluorine gas.

For example, the second heat treatment is performed by supplying the hydrogen gas, the deuterium gas, or the fluorine gas to a reactor containing the silicon carbide layer 10.

The temperature of the second heat treatment is, for example, equal to or more than 400° C. and equal to or less than 900° C.

By the second heat treatment, at least one element selected from the group consisting of hydrogen (H), deuterium (D), and fluorine (F) is segregated in the interface termination region 40. By the second heat treatment, for example, dangling bonds of carbon in the silicon carbide layer 10 are terminated.

In step S109, the gate electrode 30 is formed on the gate insulating layer 28. The gate electrode 30 is, for example, polycrystalline silicon containing n-type impurities or p-type impurities.

In step S110, the interlayer insulating film 32 is formed on the gate electrode 30. The interlayer insulating film 32 is, for example, a silicon oxide film.

In step S111, the source electrode 34 is formed. The source electrode 34 is formed on the source region 18 and the p-well contact region 20. The source electrode 34 is formed, for example, by sputtering nickel (Ni) and aluminum (Al).

In step S112, the drain electrode 36 is formed. The drain electrode 36 is formed on the back surface side of the silicon carbide layer 10. The drain electrode 36 is formed, for example, by sputtering nickel.

By the manufacturing method described above, the MOSFET 100 shown in FIG. 1 is formed.

Next, the function and effect of the semiconductor device manufacturing method and the semiconductor device according to the first embodiment will be described. The MOSFET 100 manufactured by the manufacturing method according to the first embodiment includes the interface termination region 40 with a high atomic concentration of nitrogen. The interface termination region 40 is formed by the first heat treatment (step S107) performed in an atmosphere containing nitrogen oxide gas (NOx). Therefore, through the manufacturing method according to the first embodiment, the MOSFET 100 is realized in which a decrease in carrier mobility is suppressed.

In addition, in the MOSFET 100 manufactured by the manufacturing method according to the first embodiment, the amount of defects in the gate insulating layer 28 is reduced. The amount of defects in the gate insulating layer 28 is reduced by the formation of a silicon-rich silicon oxide film (step S106) and the first heat treatment (step S107) performed in an atmosphere containing nitrogen oxide gas (NOx). Therefore, the MOSFET 100 is realized in which a decrease in carrier mobility, a decrease in threshold voltage, a fluctuation in threshold voltage, an increase in the leakage current of the gate insulating layer, or a decrease in the reliability of the gate insulating layer due to defects in the gate insulating layer 28 is suppressed.

In addition, the MOSFET 100 manufactured by the manufacturing method according to the first embodiment includes the interface termination region 40 with a high atomic concentration of at least one element selected from the group consisting of hydrogen (H), deuterium (D), and fluorine (F). The interface termination region 40 is formed by the second heat treatment (step S108) performed in an atmosphere containing at least one element selected from the group consisting of hydrogen (H), deuterium (D), and fluorine (F). Therefore, through the manufacturing method according to the first embodiment, the MOSFET 100 is realized in which a fluctuation in threshold voltage due to AC stress is suppressed.

Hereinafter, detailed explanation will be given.

When forming a MOSFET using silicon carbide, there is a problem that the mobility of carriers decreases. One factor that decreases the mobility of carriers is thought to be the interface state between the silicon carbide layer and the gate insulating layer. It is thought that the interface state is caused by the dangling bonds present on the surface of the silicon carbide layer.

In the semiconductor device manufacturing method according to the first embodiment, the first heat treatment (step S107) is performed in an atmosphere containing nitrogen oxide gas (NOx). By the first heat treatment, the interface termination region 40 is formed. In the interface termination region 40, nitrogen (N) terminates dangling bonds of silicon in the silicon carbide layer 10. Therefore, since the number of dangling bonds on the surface of the silicon carbide layer is reduced, the MOSFET 100 is realized in which a decrease in carrier mobility is suppressed.

From the viewpoint of suppressing a decrease in carrier mobility, the atomic concentration of nitrogen at the peak of the concentration distribution of nitrogen in the interface termination region 40 is preferably equal to or more than 1×10²¹ cm⁻³, more preferably equal to or more than 1×10²² cm⁻³.

When forming a MOSFET using silicon carbide, there is a problem that the mobility of carriers decreases or the threshold voltage fluctuates. In addition, there is a problem that the leakage current of the gate insulating layer increases or the reliability of the gate insulating layer decreases. One factor that causes the above-described problems is thought to be defects such as nitrogen defects or carbon defects in the gate insulating layer.

Defects in the gate insulating layer are thought to be factors that cause the above-described problems by forming trap levels in the gate insulating layer.

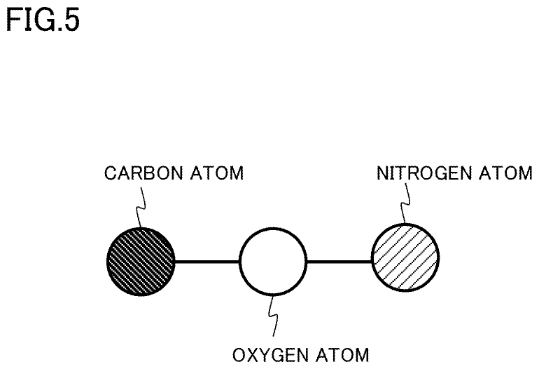

FIG. 5 is an explanatory diagram of an example of defects in the gate insulating layer. FIG. 5 shows a complex containing a carbon atom bonded to an oxygen atom and a nitrogen atom bonded to the oxygen atom. FIG. 5 shows a C—O—N bond. The carbon atom and the nitrogen atom of the C—O—N bond are present in the silicon site of silicon oxide.

As a semiconductor device manufacturing method according to a comparative example, a case is considered in which a silicon oxide film having a stoichiometric composition is formed instead of forming a silicon-rich silicon oxide film (step S106). In other words, a case of forming a silicon oxide film represented by the chemical formula of SiO₂ is considered.

By the first heat treatment (step S107) performed in an atmosphere containing nitrogen oxide gas (NOx), the silicon carbide layer 10 is oxidized. When the silicon carbide layer 10 is oxidized, excess carbon (C) is diffused into the silicon oxide film from the silicon carbide layer 10. For example, carbon diffused into the silicon oxide film and nitrogen contained in the nitrogen oxide gas enter the silicon sites of the silicon oxide in the silicon oxide film, thereby forming a C—O—N bond. If the C—O—N bond remains in the gate insulating layer, problems such as a decrease in carrier mobility, a fluctuation in threshold voltage, an increase in the leakage current of the gate insulating layer, and a decrease in the reliability of the gate insulating layer occur.

In the semiconductor device manufacturing method according to the first embodiment, a silicon-rich silicon oxide film is formed (step S106). Even if the silicon carbide layer 10 is oxidized to form C—O—N bonds by the first heat treatment (step S107) performed in an atmosphere containing nitrogen oxide gas (NOx), carbon or nitrogen in the silicon site is substituted by the excess silicon contained in the silicon oxide film.

The substituted carbon is removed from the silicon oxide film as carbon monoxide gas. In addition, the substituted nitrogen is removed from the silicon oxide film as nitrogen gas. For this reason, C—O—N bonds are removed from the silicon oxide film. Therefore, C—O—N bonds are prevented from remaining in the gate insulating layer. As a result, according to the semiconductor device manufacturing method according to the first embodiment, the MOSFET 100 is realized in which a decrease in carrier mobility, a decrease in threshold voltage, a fluctuation in threshold voltage, an increase in the leakage current of the gate insulating layer, or a decrease in the reliability of the gate insulating layer due to defects in the gate insulating layer 28 is suppressed.

From the viewpoint of increasing excess silicon and removing C—O—N bonds from the silicon oxide film, the atomic concentration of oxygen (O) contained in the silicon oxide film is preferably equal to or less than 1.99 times the atomic concentration of silicon (Si), more preferably equal to or less than 1.95 times the atomic concentration of silicon (Si).

From the viewpoint of facilitating the formation of a silicon oxide film, the atomic concentration of oxygen (O) contained in the silicon oxide film is preferably equal to or more than 1.9 times the atomic concentration of silicon (Si).

The temperature of the first heat treatment performed in an atmosphere containing nitrogen oxide gas (NOx) is preferably equal to or more than 900° C. and equal to or less than 1250° C., more preferably equal to or more than 925° C. and equal to or less than 1100° C., and even more preferably equal to or more than 950° C. and equal to or less than 1000° C. By exceeding the above lower limit, strain in the silicon oxide film is reduced. In addition, by falling below the above upper limit, oxidation of the silicon carbide layer is suppressed.

In the semiconductor device manufacturing method according to the first embodiment, it is preferable not to perform heat treatment at a temperature exceeding the temperature of the first heat treatment in an atmosphere containing nitrogen before the first heat treatment after forming the silicon oxide film. For example, in order to suppress the oxidation of the silicon carbide layer, heat treatment for terminating dangling bonds on the surface with nitrogen may be performed in an oxygen-free atmosphere. As described above, in the semiconductor device manufacturing method according to the first embodiment, defects in the gate insulating layer 28 can be suppressed even when the silicon carbide layer is oxidized. Therefore, additional heat treatment in an atmosphere containing nitrogen does not need to be performed before the first heat treatment. Since heat treatment in an atmosphere containing nitrogen is not performed before the first heat treatment after forming the silicon oxide film, the semiconductor device manufacturing method can be simplified.

When forming a MOSFET with a trench gate structure using silicon carbide, there is a problem that a fluctuation in threshold voltage occurs due to AC stress. One factor is thought to be the interface state between the silicon carbide layer and the gate insulating layer. It is thought that the interface state is caused particularly by the dangling bonds of carbon on the inner surface of the trench. It is thought that charges injected to the interface between the semiconductor layer and the gate insulating film by the application of AC stress are trapped in the interface state and the fluctuation in threshold voltage will occur. The fluctuation in threshold voltage will increase with increasing number of switching of AC stress.

In the semiconductor device manufacturing method according to the first embodiment, after the first heat treatment (step S107) is performed in an atmosphere containing nitrogen oxide gas (NOx), the second heat treatment (step S108) is performed in an atmosphere containing at least one element selected from the group consisting of hydrogen (H), deuterium (D), and fluorine (F). By performing the second heat treatment, in the interface termination region 40, at least one element selected from the group consisting of hydrogen (H), deuterium (D), and fluorine (F) terminates the dangling bonds of carbon in the silicon carbide layer 10. Therefore, since the number of dangling bonds of carbon on the inner surface of the trench is reduced, the MOSFET 100 is realized in which a fluctuation in threshold voltage due to AC stress is suppressed.

The temperature of the second heat treatment performed in an atmosphere containing at least one element selected from the group consisting of hydrogen (H), deuterium (D), and fluorine (F) is preferably equal to or more than 400° C. and equal to or less than 900° C., more preferably equal to or more than 550° C. and equal to or less than 850° C., and even more preferably equal to or more than 700° C. and equal to or less than 800° C. By exceeding the above lower limit, the number of dangling bonds of carbon is reduced. In addition, by falling below the above upper limit, the second heat treatment becomes easier.

In addition, the second heat treatment (step S108) performed in an atmosphere containing at least one element selected from the group consisting of hydrogen (H), deuterium (D), and fluorine (F) is preferably performed after the first heat treatment (step S107) is performed in an atmosphere containing nitrogen oxide gas (NOx). If the second heat treatment is performed before the first heat treatment, excess silicon in the silicon oxide film and the at least one element may be bonded to suppress the diffusion of the at least one element in the silicon oxide film.

In the MOSFET 100 according to the first embodiment, for example, a threshold voltage fluctuation when high frequency AC stress of 1 MHz from −5 MV/cm to 5 MV/cm is applied for 100 hours between the silicon carbide layer 10 and the gate electrode 30 is less than 0.1 V. Therefore, the MOSFET 100 has excellent AC stress tolerance. For example, in case of a trench gate type MOSFET which is not manufactured by the semiconductor device manufacturing method according to the first embodiment, a threshold voltage fluctuation when AC stress of 1 MHz from −5 MV/cm to 5 MV/cm is applied for 100 hours between the silicon carbide layer and the gate electrode may be larger than 1 V.

From the viewpoint of suppressing a fluctuation in threshold voltage due to AC stress, it is preferable that in the interface termination region 40, the amount of the at least one element bonded to carbon (C) is larger than the amount of the at least one element bonded to silicon (Si).

From the viewpoint of suppressing a fluctuation in threshold voltage due to AC stress, the atomic concentration of the at least one element at the peak of the concentration distribution of the at least one element in the interface termination region 40 is preferably equal to or more than 1×10¹⁷ cm⁻³, more preferably equal to or more than 1×10¹⁸ cm⁻³, and even more preferably equal to or more than 1×10¹⁹ cm⁻³.

As described above, according to the first embodiment, a semiconductor device manufacturing method that reduces the amount of defects in the gate insulating layer is realized. In addition, according to the first embodiment, a semiconductor device with excellent AC stress tolerance is realized.

### Second Embodiment

A semiconductor device manufacturing method according to a second embodiment includes: forming a silicon oxide film on a silicon carbide layer, the atomic concentration of oxygen (O) in the silicon oxide film being less than twice the atomic concentration of silicon (Si) in the silicon oxide film; forming a first silicon film on the silicon oxide film; performing a first heat treatment in an atmosphere containing nitrogen oxide gas after forming the first silicon film; and forming a second silicon film containing boron (B) and thicker than the first silicon film after the first heat treatment. The semiconductor device manufacturing method according to the second embodiment is different from the semiconductor device manufacturing method according to the first embodiment in that a trench is not formed and the first heat treatment is performed in an atmosphere containing nitrogen oxide gas after forming the first silicon film.

A semiconductor device according to the second embodiment includes a silicon carbide layer, a gate electrode containing polycrystalline silicon containing boron (B), a silicon oxide layer provided between the silicon carbide layer and the gate electrode, a first region provided between the silicon carbide layer and the silicon oxide layer and containing nitrogen, and a second region provided between the silicon oxide layer and the gate electrode and containing nitrogen. The semiconductor device according to the second embodiment is manufactured by using, for example, the semiconductor device manufacturing method according to the second embodiment. The semiconductor device according to the second embodiment is different from the semiconductor device according to the first embodiment in that a trench is not provided and a second region provided between the silicon oxide layer and the gate electrode and containing nitrogen is included.

Hereinafter, the description of a part of the content overlapping the first embodiment may be omitted.

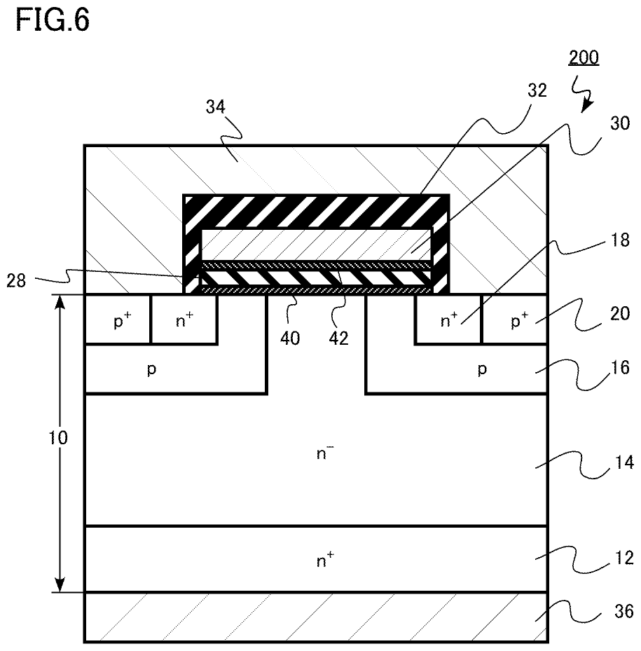

FIG. 6 is a schematic cross-sectional view of the semiconductor device according to the second embodiment. The semiconductor device is a MOSFET 200. The MOSFET 200 is a double implantation MOSFET (DIMOSFET) in which a p-well and a source region are formed by ion implantation. In addition, the MOSFET 200 is an n-channel MOSFET having electrons as carriers.

The MOSFET 200 includes a silicon carbide layer 10, a gate insulating layer 28 (silicon oxide layer), a gate electrode 30, an interlayer insulating film 32, a source electrode 34, a drain electrode 36, an interface termination region 40 (first region), and a diffusion prevention region 42 (second region).

The silicon carbide layer 10 includes a drain region 12, a drift region 14, a p-well region 16, a source region 18, and a p-well contact region 20.

The silicon carbide layer 10 is, for example, a single crystal of 4H—SiC. The silicon carbide layer 10 is disposed between the source electrode 34 and the drain electrode 36.

The surface of the silicon carbide layer 10 is a face inclined by an angle equal to or more than 0 degrees and equal to or less than 8 degrees with respect to the silicon face, and the back surface of the silicon carbide layer 10 is a face inclined by an angle equal to or more than 0 degrees and equal to or less than 8 degrees with respect to the carbon face. The surface of the silicon carbide layer 10 has an off angle equal to or more than 0 degrees and equal to or less than 8 degrees with respect to the silicon face.

The drain region 12 is an n⁺-type SiC. The drain region 12 contains, for example, nitrogen (N) as an n-type impurity. The n-type impurity concentration in the drain region 12 is, for example, equal to or more than 1×10¹⁸ cm⁻³ and equal to or less than 1×10²¹ cm⁻³.

The drift region 14 is provided on the drain region 12. The drift region 14 is an n⁻-type SiC. The drift region 14 contains, for example, nitrogen as an n-type impurity.

The n-type impurity concentration in the drift region 14 is lower than the n-type impurity concentration in the drain region 12. The n-type impurity concentration in the drift region 14 is, for example, equal to or more than 1×10¹⁵ cm⁻³ and equal to or less than 2×10¹⁶ cm⁻³. The drift region 14 is, for example, a SiC epitaxial growth layer formed on the drain region 12 by epitaxial growth.

The thickness of the drift region 14 is, for example, equal to or more than 5 μm and equal to or less than 100 μm.

The p-well region 16 is provided on a partial surface of the drift region 14. The p-well region 16 is a p-type SiC. The p-well region 16 contains, for example, aluminum (Al) as a p-type impurity. The p-type impurity concentration in the p-well region 16 is, for example, equal to or more than 1×10¹⁶ cm⁻³ and equal to or less than 1×10²⁰ cm⁻³.

The depth of the p-well region 16 is, for example, equal to or more than 0.4 μm and equal to or less than 0.8 μm. The p-well region 16 functions as a channel region of the MOSFET 200.

The source region 18 is provided on a partial surface of the p-well region 16. The source region 18 is an n⁺-type SiC. The source region 18 contains, for example, phosphorus (P) as an n-type impurity. The n-type impurity concentration in the source region 18 is, for example, equal to or more than 1×10¹⁸ cm⁻³ and equal to or less than 1×10²² cm⁻³.

The depth of the source region 18 is smaller than the depth of the p-well region 16. The depth of the source region 18 is, for example, equal to or more than 0.2 μm and equal to or less than 0.4 μm.

The p-well contact region 20 is provided on a partial surface of the p-well region 16. The p-well contact region 20 is provided on the side of the source region 18. The p-well contact region 20 is a p⁺-type SiC.

The p-well contact region 20 contains, for example, aluminum as a p-type impurity. The p-type impurity concentration in the p-well contact region 20 is, for example, equal to or more than 1×10¹⁸ cm⁻³ and equal to or less than 1×10²² cm⁻³.

The depth of the p-well contact region 20 is smaller than the depth of the p-well region 16. The depth of the p-well contact region 20 is, for example, equal to or more than 0.2 μm and equal to or less than 0.4 μm.

The gate insulating layer 28 is provided between the silicon carbide layer 10 and the gate electrode 30. The gate insulating layer 28 is provided between the drift region 14 and the p-well region 16 and the gate electrode 30. The gate insulating layer 28 is provided above the drift region 14 and the p-well region 16. The gate insulating layer 28 is continuously formed on the surfaces of the drift region 14 and the p-well region 16.

The gate insulating layer 28 is a silicon oxide.

The thickness of the gate insulating layer 28 is, for example, equal to or more than 30 nm and equal to or less than 100 nm. The gate insulating layer 28 functions as a gate insulating layer of the MOSFET 200.

The interface termination region 40 is disposed between the silicon carbide layer 10 and the gate insulating layer 28. The interface termination region 40 is disposed between the drift region 14 and the p-well region 16 and the gate insulating layer 28.

The interface termination region 40 contains nitrogen (N) as a termination element for terminating the dangling bond of the silicon carbide layer 10. Nitrogen (N) terminates dangling bonds of silicon in the silicon carbide layer 10, for example.

In addition, the interface termination region 40 contains at least one element selected from the group consisting of hydrogen (H), deuterium (D), and fluorine (F) as a termination element for terminating dangling bonds in the silicon carbide layer 10. The at least one element described above terminates dangling bonds of silicon in the silicon carbide layer 10, for example.

The atomic concentration of at least one element selected from the group consisting of hydrogen (H), deuterium (D), and fluorine (F) in the interface termination region 40 is lower than the atomic concentration of nitrogen (N) in the interface termination region 40, for example. The atomic concentration of at least one element selected from the group consisting of hydrogen (H), deuterium (D), and fluorine (F) in the interface termination region 40 is, for example, equal to or more than 1/10000 and equal to or less than 1/10 of the atomic concentration of nitrogen (N) in the interface termination region 40.

The diffusion prevention region 42 is disposed between the gate insulating layer 28 and the gate electrode 30.

The diffusion prevention region 42 contains nitrogen (N). The diffusion prevention region 42 contains, for example, oxygen (O). The diffusion prevention region 42 contains, for example, silicon oxynitride. The diffusion prevention region 42 has a function of preventing boron (B) contained in the gate electrode 30 from diffusing into the gate insulating layer 28 or the silicon carbide layer 10.

In addition, the diffusion prevention region 42 contains at least one element selected from the group consisting of hydrogen (H), deuterium (D), and fluorine (F). The at least one element in the diffusion prevention region 42 has a function of suppressing the generation of fixed charges at the interface between the gate insulating layer 28 and the gate electrode 30, for example.

The atomic concentration of at least one element selected from the group consisting of hydrogen (H), deuterium (D), and fluorine (F) in the diffusion prevention region 42 is lower than the atomic concentration of nitrogen (N) in the diffusion prevention region 42, for example. The atomic concentration of at least one element selected from the group consisting of hydrogen (H), deuterium (D), and fluorine (F) in the diffusion prevention region 42 is, for example, equal to or more than 1/10000 and equal to or less than 1/10 of the atomic concentration of nitrogen (N) in the diffusion prevention region 42.

Hereinafter, a case where the above-described at least one element is fluorine (F) will be described as an example.

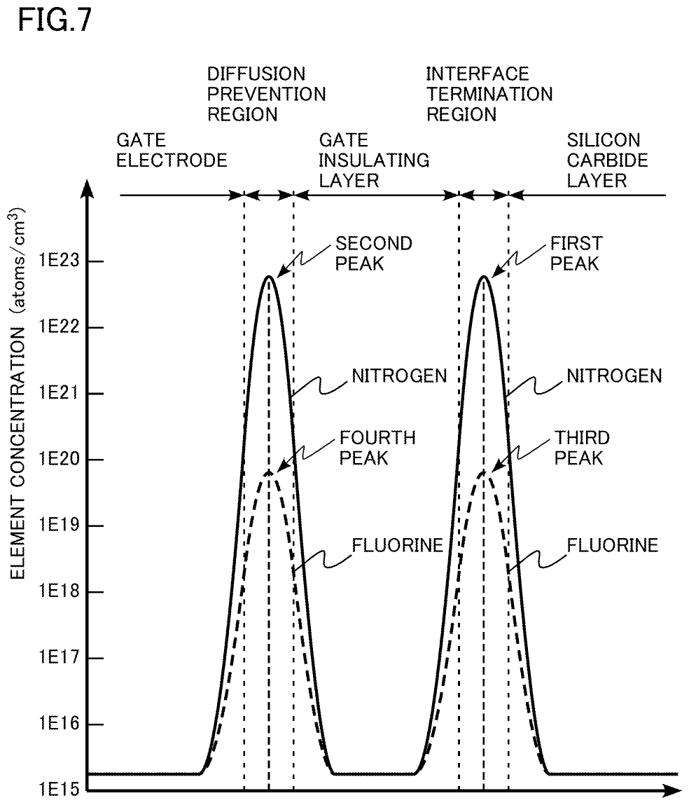

FIG. 7 is a diagram showing an example of the element concentration distribution of the semiconductor device according to the second embodiment. FIG. 7 is a diagram showing the element concentration distribution in the gate electrode 30, the diffusion prevention region 42, the gate insulating layer 28, the interface termination region 40, and the silicon carbide layer 10. FIG. 7 shows the concentration distribution of nitrogen (N) and fluorine (F).

The concentration distribution of nitrogen (N) has a first peak in the interface termination region 40. The atomic concentration of nitrogen at the first peak is, for example, equal to or more than 1×10²¹ cm⁻³ and equal to or less than 1×10²³ cm⁻³. The full width at half maximum with respect to the first peak of the nitrogen concentration distribution is, for example, equal to or less than 1 nm. Nitrogen is segregated at the interface between the silicon carbide layer 10 and the gate insulating layer 28.

The concentration distribution of nitrogen (N) has a second peak in the diffusion prevention region 42. The atomic concentration of nitrogen at the second peak is, for example, equal to or more than 1×10²¹ cm⁻³ and equal to or less than 1×10²³ cm⁻³. The full width at half maximum with respect to the second peak of the nitrogen concentration distribution is, for example, equal to or less than 1 nm. Nitrogen is segregated at the interface between the gate insulating layer 28 and the gate electrode 30.

The concentration distribution of fluorine (F) has a third peak in the interface termination region 40. The atomic concentration of fluorine at the third peak is, for example, equal to or more than 1×10¹⁷ cm⁻³ and equal to or less than 1×10²¹ cm⁻³. The full width at half maximum with respect to the third peak of the fluorine concentration distribution is, for example, equal to or less than 1 nm. Fluorine is segregated at the interface between the silicon carbide layer 10 and the gate insulating layer 28.

Fluorine terminates dangling bonds of silicon, for example. In the interface termination region 40, for example, the amount of fluorine bonded to silicon is larger than the amount of fluorine bonded to carbon. In the interface termination region 40, for example, the concentration of fluorine bonded to silicon is higher than the concentration of fluorine bonded to carbon.

The concentration distribution of fluorine (F) has a fourth peak in the diffusion prevention region 42. The atomic concentration of fluorine at the fourth peak is, for example, equal to or more than 1×10¹⁷ cm⁻³ and equal to or less than 1×10²¹ cm⁻³. The full width at half maximum with respect to the fourth peak of the fluorine concentration distribution is, for example, equal to or less than 1 nm. Fluorine is segregated at the interface between the gate insulating layer 28 and the gate electrode 30.

The gate electrode 30 is provided on the gate insulating layer 28. The gate insulating layer 28 is interposed between the gate electrode 30 and the silicon carbide layer 10. The gate insulating layer 28 is interposed between the gate electrode 30 and the drift region 14. The gate insulating layer 28 is interposed between the gate electrode 30 and the p-well region 16.

The gate electrode 30 contains polycrystalline silicon containing boron (B). The gate electrode 30 is, for example, a polycrystalline silicon layer containing boron (B). The gate electrode 30 may have a stacked structure of a polycrystalline silicon layer containing boron (B) and a metal layer.

The atomic concentration of boron (B) contained in the gate electrode 30 is, for example, equal to or more than 1×10²⁰ cm⁻³.

The interlayer insulating film 32 is formed on the gate electrode 30. The interlayer insulating film 32 is, for example, a silicon oxide film.

The source electrode 34 is electrically connected to the source region 18 and the p-well contact region 20. The source electrode 34 also functions as a p-well electrode for applying an electric potential to the p-well region 16.

The source electrode 34 has, for example, a stacked structure of a barrier metal layer of nickel (Ni) and a metal layer of aluminum on the barrier metal layer. The barrier metal layer of nickel and the silicon carbide layer may react with each other to form nickel silicide. The nickel silicide is, for example, NiSi or Ni₂Si. The barrier metal layer formed of nickel and the metal layer formed of aluminum may form an alloy by reaction.

The drain electrode 36 is provided on a side of the silicon carbide layer 10 opposite to the source electrode 34, that is, on the back surface side of the silicon carbide layer 10. The drain electrode 36 is, for example, nickel. Nickel may react with the drain region 12 to form nickel silicide. The nickel silicide is, for example, NiSi or Ni₂Si.

In addition, in the MOSFET 200 according to the second embodiment, the n-type impurity is, for example, nitrogen or phosphorus. Arsenic (As) or antimony (Sb) can also be applied as an n-type impurity.

In addition, in the MOSFET 200 according to the second embodiment, the p-type impurity is, for example, aluminum. Boron (B), gallium (Ga), and indium (In) can also be applied as p-type impurities.

Next, an example of a semiconductor device manufacturing method according to the second embodiment will be described.

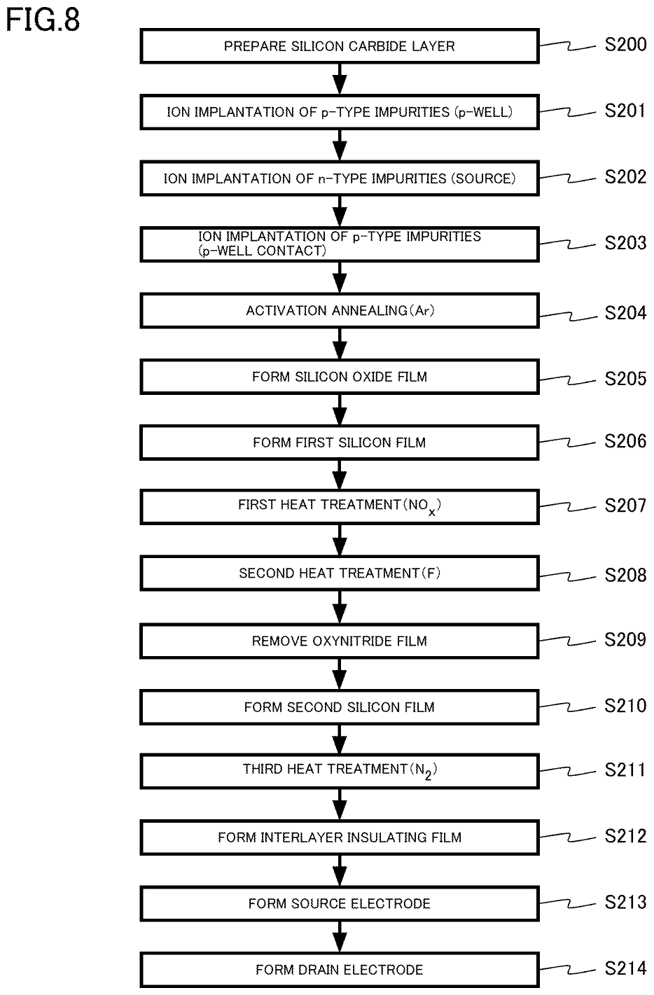

FIG. 8 is a process flow diagram of the semiconductor device manufacturing method according to the second embodiment.

As shown in FIG. 8, the semiconductor device manufacturing method according to the second embodiment includes preparation of a silicon carbide layer (step S200), ion implantation of p-type impurities (step S201), ion implantation of n-type impurities (step S202), ion implantation of p-type impurities (step S203), activation annealing (step S204), formation of a silicon oxide film (step S205), formation of a first silicon film (step S206), first heat treatment (step S207), second heat treatment (step S208), removal of an oxynitride film (step S209), formation of a second silicon film (step S210), third heat treatment (step S211), formation of an interlayer insulating film (step S212), formation of a source electrode (step S213), and formation of a drain electrode (step S214).

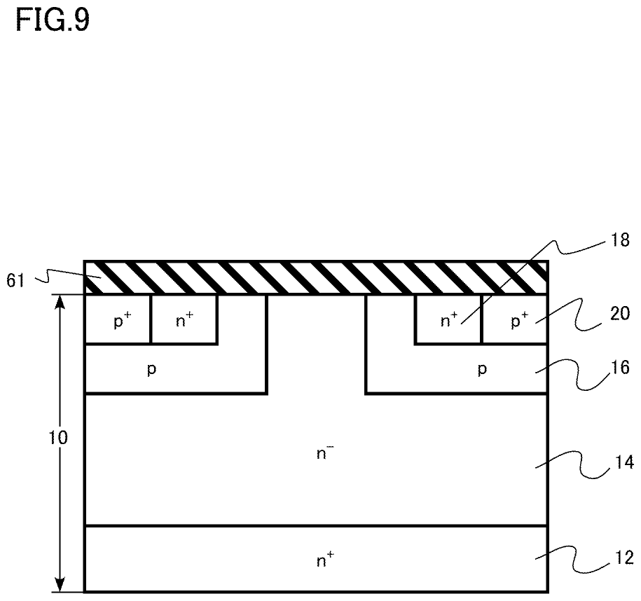

FIGS. 9 to 14 are schematic cross-sectional views illustrating the semiconductor device manufacturing method according to the second embodiment. FIGS. 9 to 14 are cross sections corresponding to FIG. 7.

In step S200, the silicon carbide layer 10 is prepared. The surface of the silicon carbide layer 10 is a face inclined at an angle equal to or more than 0 degrees and equal to or less than 8 degrees with respect to the {0001}face.

The silicon carbide layer 10 includes an n⁺-type drain region 12 and an n⁻-type drift region 14. The drift region 14 is formed on the drain region 12 by using an epitaxial growth method, for example.

The drain region 12 contains nitrogen as an n-type impurity. The n-type impurity concentration in the drain region 12 is, for example, equal to or more than 1×10¹⁸ cm⁻³ and equal to or less than 1×10²¹ cm⁻³.

The drift region 14 contains nitrogen as an n-type impurity. The n-type impurity concentration in the drift region 14 is, for example, equal to or more than 1×10¹⁵ cm⁻³ and equal to or less than 2×10¹⁶ cm⁻³. The thickness of the drift region 14 is, for example, equal to or more than 5 μm and equal to or less than 100 μm.

In step S201, first, a first mask material is formed by patterning using photolithography and etching.

Then, by using the first mask material as an ion implantation mask, aluminum (Al), which is a p-type impurity, is ion-implanted into the drift region 14. By the ion implantation, the p-well region 16 is formed.

In step S202, first, a second mask material is formed by patterning using photolithography and etching. Then, by using the second mask material as an ion implantation mask, phosphorus (P), which is an n-type impurity, is ion-implanted into the drift region 14 to form the source region 18.

In step S203, first, a third mask material is formed by patterning using photolithography and etching. By using the third mask material as an ion implantation mask, aluminum (Al), which is a p-type impurity, is ion-implanted into the drift region 14 to form the p-well contact region 20.

Then, a carbon film is formed on the surface of the silicon carbide layer 10. The carbon film is formed by using, for example, a sputtering method. The carbon film suppresses the surface of the silicon carbide layer 10 from being roughened during the subsequent activation annealing.

In step S204, activation annealing is performed. By the activation annealing, p-type impurities and n-type impurities ion-implanted into the silicon carbide layer 10 are activated. The activation annealing is performed, for example, in an argon atmosphere. The temperature of the activation annealing is, for example, equal to or more than 1600° C. and equal to or less than 1800° C.

Then, the carbon film on the surface of the silicon carbide layer 10 is removed. The carbon film is removed, for example, by an ashing treatment using oxygen plasma.

In step S205, a silicon oxide film 61 is formed on the surface of the silicon carbide layer 10 (FIG. 9). The silicon oxide film 61 finally becomes a part of the gate insulating layer 28.

The atomic concentration of oxygen (O) contained in the silicon oxide film 61 is less than twice the atomic concentration of silicon (Si). The silicon oxide film 61 is a silicon-rich silicon oxide film. When the chemical composition of the silicon oxide film 61 is expressed as SiO_{2-δ}, for example, 0.01≤δ≤0.1 is satisfied. In other words, the oxygen vacancies in the silicon oxide film 61 are, for example, equal to or more than 0.5% and equal to or less than 5%. In other words, for example, the atomic concentration of oxygen (O) contained in the silicon oxide film 61 is equal to or more than 1.9 times and equal to or less than 1.99 times the atomic concentration of silicon (Si).

The silicon oxide film 61 is formed by using, for example, a vapor deposition method. The silicon oxide film 61 is formed by using, for example, a chemical vapor deposition method (CVD method) or a physical vapor deposition method (PVD method). The silicon oxide film 61 is a deposited film. The thickness of the silicon oxide film 61 is, for example, equal to or more than 30 nm and equal to or less than 100 nm.

The silicon oxide film 61 is, for example, a silicon oxide film formed by a CVD method using tetraethyl orthosilicate (TEOS) as a source gas. In addition, the silicon oxide film 61 is, for example, a silicon oxide film formed by a CVD method using dichlorosilane gas (SiH₂Cl₂) and dinitrogen monoxide gas (N₂O) as source gases.

The silicon oxide film 61 is formed at a temperature equal to or less than 600° C., for example.

For example, by lowering the partial pressure of oxygen in the atmosphere when forming the silicon oxide film 61, it is possible to form a silicon oxide film that is entirely rich in silicon.

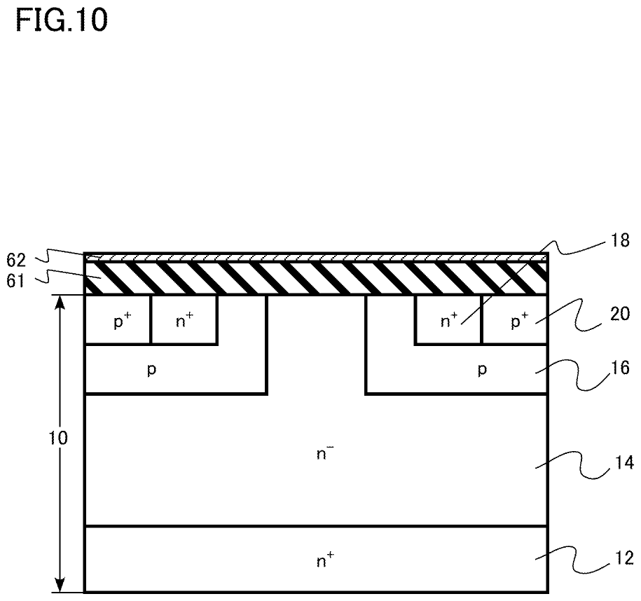

In step S206, the first silicon film 62 is formed on the silicon oxide film 61 (FIG. 10). The first silicon film 62 is, for example, polycrystalline silicon or amorphous silicon. The first silicon film 62 finally becomes a part of the gate electrode 30.

The first silicon film 62 may or may not contain boron (B). The atomic concentration of boron (B) contained in the first silicon film 62 is lower than the atomic concentration of boron (B) contained in a second silicon film 64. The first silicon film 62 is, for example, non-doped silicon to which boron is not actively added.

The first silicon film 62 is formed by using, for example, a CVD method.

The thickness of the first silicon film 62 is, for example, equal to or more than 3 nm and equal to or less than 20 nm.

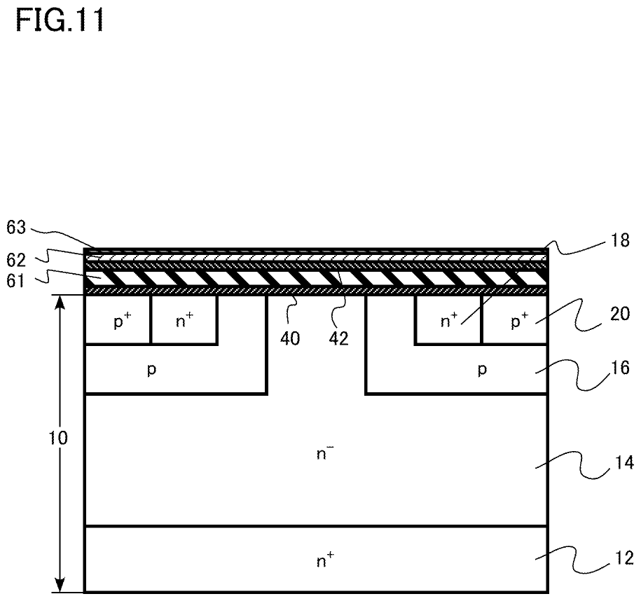

In step S207, a first heat treatment is performed (FIG. 11). The first heat treatment is performed in an atmosphere containing nitrogen oxide gas (NOx). The nitrogen oxide gas is, for example, a nitric oxide gas (NO). In addition, the nitrogen oxide gas is, for example, a dinitrogen monoxide gas (N₂O).

For example, the first heat treatment is performed by supplying the nitrogen oxide gas (NOx) to a reactor containing the silicon carbide layer 10.

The temperature of the first heat treatment is, for example, equal to or more than 900° C. and equal to or less than 1250° C.

The partial pressure of the nitrogen oxide gas in the atmosphere of the first heat treatment is, for example, equal to or more than 10%.

By the first heat treatment, the interface termination region 40 is formed. By the first heat treatment, nitrogen is segregated at the interface between the silicon carbide layer 10 and the silicon oxide film 61. By the first heat treatment, for example, dangling bonds of silicon in the silicon carbide layer 10 are terminated.

By the first heat treatment, the diffusion prevention region 42 is formed. By the first heat treatment, nitrogen is segregated at the interface between the silicon oxide film 61 and the first silicon film 62.

By the first heat treatment, the surface of the first silicon film 62 is oxynitrided. By the first heat treatment, for example, an oxynitride film 63 containing oxygen (O) and nitrogen (N) is formed on the first silicon film 62.

In step S208, a second heat treatment is performed. The second heat treatment is performed in an atmosphere containing at least one element selected from the group consisting of hydrogen (H), deuterium (D), and fluorine (F).

The atmosphere of the second heat treatment contains, for example, hydrogen gas, deuterium gas, or fluorine gas.

For example, the second heat treatment is performed by supplying fluorine gas to a reactor containing the silicon carbide layer 10.

The temperature of the second heat treatment is, for example, equal to or more than 400° C. and equal to or less than 900° C.

By the second heat treatment, at least one element selected from the group consisting of hydrogen (H), deuterium (D), and fluorine (F) is segregated in the interface termination region 40. By the second heat treatment, for example, dangling bonds of silicon in the silicon carbide layer 10 are terminated.

By the second heat treatment, at least one element selected from the group consisting of hydrogen (H), deuterium (D), and fluorine (F) is segregated in the diffusion prevention region 42.

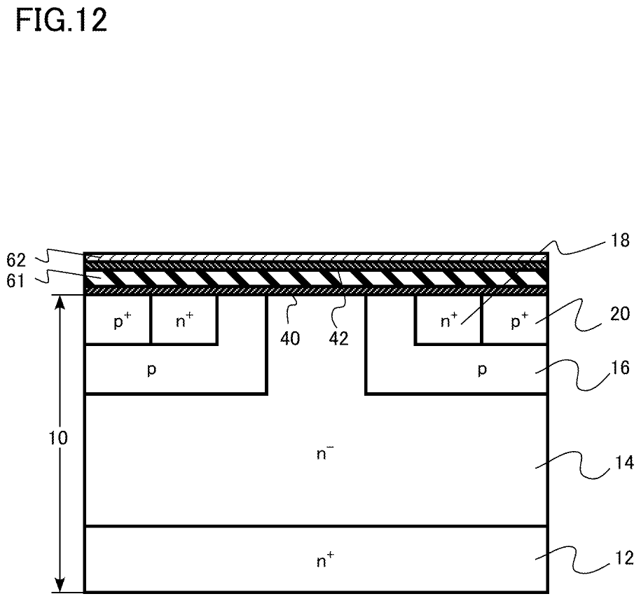

In step S209, the oxynitride film is removed (FIG. 12). In step S209, the oxynitride film 63 on the surface of the first silicon film 62 is removed. The oxynitride film 63 is removed by using, for example, a wet etching method.

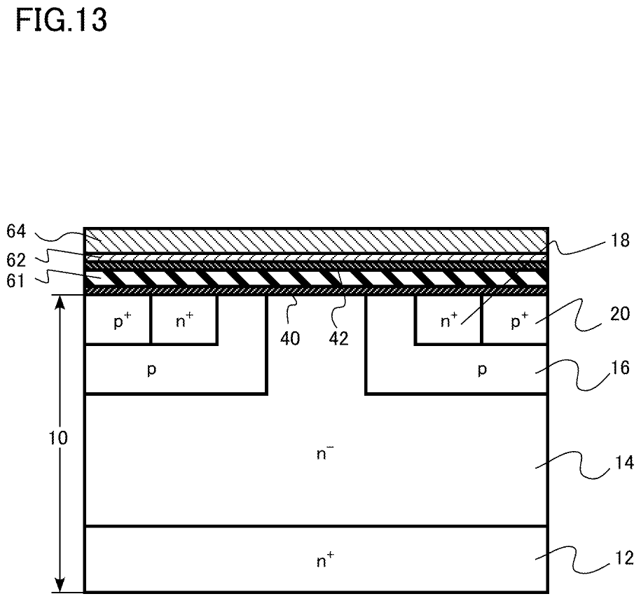

In step S210, the second silicon film 64 containing boron (B) is formed on the first silicon film 62 (FIG. 13). The second silicon film 64 is, for example, polycrystalline silicon or amorphous silicon. The second silicon film 64 finally becomes a part of the gate electrode 30.

The atomic concentration of boron (B) contained in the second silicon film 64 is higher than the atomic concentration of boron (B) contained in the first silicon film 62. The atomic concentration of boron (B) contained in the second silicon film 64 is, for example, equal to or more than 1×10²⁰ cm⁻³.

The thickness of the second silicon film 64 is larger than the thickness of the first silicon film 62. The thickness of the second silicon film 64 is, for example, equal to or more than 50 nm and equal to or less than 200 nm.

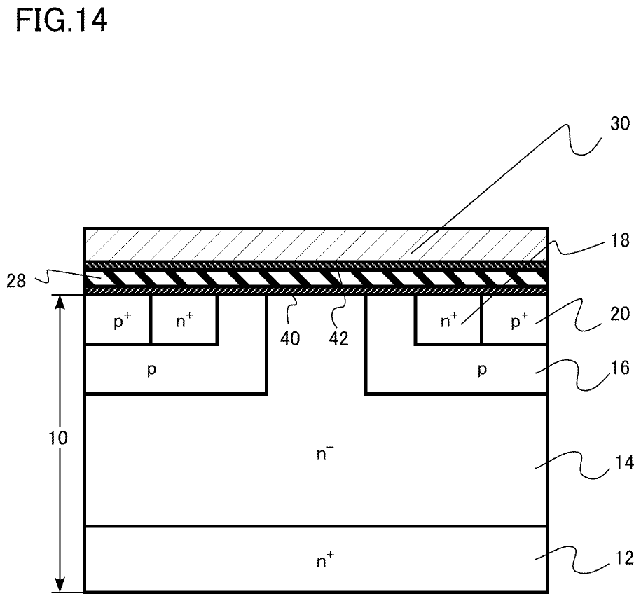

In step S211, a third heat treatment is performed to activate boron (B) contained in the second silicon film 64 (FIG. 14). The third heat treatment is performed, for example, in a non-oxidizing atmosphere. The third heat treatment is performed, for example, in a nitrogen atmosphere or an argon atmosphere. The temperature of the third heat treatment is, for example, equal to or more than 800° C. and equal to or less than 1000° C.

By the third heat treatment, for example, boron (B) contained in the second silicon film 64 is diffused into the first silicon film 62. Since the diffusion of boron in the silicon film is very fast, the amount of boron diffused into the first silicon film 62 can be increased to the same level as the amount of boron contained in the second silicon film 64. On the other hand, the diffusion prevention region 42 prevents the diffusion of boron into the gate insulating layer 28.

In step S212, the interlayer insulating film 32 is formed on the gate electrode 30. The interlayer insulating film 32 is, for example, a silicon oxide film.

In step S213, the source electrode 34 is formed. The source electrode 34 is formed on the source region 18 and the p-well contact region 20. The source electrode 34 is formed, for example, by sputtering nickel (Ni) and aluminum (Al).

In step S214, the drain electrode 36 is formed. The drain electrode 36 is formed on the back surface side of the silicon carbide layer 10. The drain electrode 36 is formed, for example, by sputtering nickel.

By the manufacturing method described above, the MOSFET 200 shown in FIG. 7 is formed.

Next, the function and effect of the semiconductor device manufacturing method and the semiconductor device according to the second embodiment will be described.

The MOSFET 200 manufactured by the manufacturing method according to the second embodiment includes the interface termination region 40 with a high atomic concentration of nitrogen. The interface termination region 40 is formed by the first heat treatment (step S207) performed in an atmosphere containing nitrogen oxide gas (NOx). Therefore, through the manufacturing method according to the second embodiment, the MOSFET 200 is realized in which a decrease in carrier mobility is suppressed.

In addition, the MOSFET 200 manufactured by the manufacturing method according to the second embodiment includes the interface termination region 40 with a high atomic concentration of at least one element selected from the group consisting of hydrogen (H), deuterium (D), and fluorine (F). The interface termination region 40 is formed by the second heat treatment (step S108) performed in an atmosphere containing at least one element selected from the group consisting of hydrogen (H), deuterium (D), and fluorine (F). Therefore, through the manufacturing method according to the second embodiment, the MOSFET 200 is realized in which a decrease in carrier mobility is suppressed.

In addition, in the MOSFET 200 manufactured by the manufacturing method according to the second embodiment, the amount of defects in the gate insulating layer 28 is reduced. The amount of defects in the gate insulating layer 28 is reduced by the formation of a silicon-rich silicon oxide film (step S205) and the first heat treatment (step S207) performed in an atmosphere containing nitrogen oxide gas (NOx). Therefore, the MOSFET 200 is realized in which a decrease in carrier mobility, a decrease in threshold voltage, a fluctuation in threshold voltage, an increase in the leakage current of the gate insulating layer, or a decrease in the reliability of the gate insulating layer due to defects in the gate insulating layer 28 is suppressed.

In addition, the MOSFET 200 manufactured by the manufacturing method according to the second embodiment includes the diffusion prevention region 42 with a high atomic concentration of nitrogen. The diffusion prevention region 42 is formed by the first heat treatment (step S207) performed in an atmosphere containing nitrogen oxide gas (NOx). Therefore, since the diffusion of boron (B) contained in the gate electrode 30 is suppressed by the manufacturing method according to the second embodiment, the MOSFET 200 is realized in which a fluctuation in threshold voltage is suppressed.

In addition, the MOSFET 200 manufactured by the manufacturing method according to the second embodiment includes the diffusion prevention region 42 with a high atomic concentration of at least one element selected from the group consisting of hydrogen (H), deuterium (D), and fluorine (F). The diffusion prevention region 42 is formed by the first heat treatment (step S207) performed in an atmosphere containing nitrogen oxide gas (NOx). Therefore, since the generation of fixed charges is suppressed by the manufacturing method according to the second embodiment, the MOSFET 200 is realized in which a fluctuation in threshold voltage is suppressed.

Hereinafter, detailed explanation will be given.

When forming a MOSFET using silicon carbide, there is a problem that the mobility of carriers decreases. One factor that decreases the mobility of carriers is thought to be the interface state between the silicon carbide layer and the gate insulating layer. It is thought that the interface state is caused by the dangling bonds present on the surface of the silicon carbide layer.

In the semiconductor device manufacturing method according to the second embodiment, the first heat treatment (step S207) is performed in an atmosphere containing nitrogen oxide gas (NOx). By the first heat treatment, the interface termination region 40 is formed. In the interface termination region 40, nitrogen (N) terminates dangling bonds of silicon in the silicon carbide layer 10. Therefore, since the number of dangling bonds on the surface of the silicon carbide layer is reduced, the MOSFET 200 is realized in which a decrease in carrier mobility is suppressed.

From the viewpoint of suppressing a decrease in carrier mobility, the atomic concentration of nitrogen at the first peak of the concentration distribution of nitrogen in the interface termination region 40 is preferably equal to or more than 1×10²¹ cm⁻³, more preferably equal to or more than 1×10²² cm⁻³.

In the semiconductor device manufacturing method according to the second embodiment, the second heat treatment (step S208) is performed in an atmosphere containing at least one element selected from the group consisting of hydrogen (H), deuterium (D), and fluorine (F). By the second heat treatment, the interface termination region 40 is formed. In the interface termination region 40, the at least one element terminates dangling bonds of silicon in the silicon carbide layer 10. Therefore, since the number of dangling bonds on the surface of the silicon carbide layer is reduced, the MOSFET 200 is realized in which a decrease in carrier mobility is suppressed.

From the viewpoint of suppressing a decrease in carrier mobility, the atomic concentration of the at least one element at the third peak of the concentration distribution of the at least one element in the interface termination region 40 is preferably equal to or more than 1×10¹⁷ cm⁻³, more preferably equal to or more than 1×10¹⁸ cm⁻³, and even more preferably equal to or more than 1×10¹⁹ cm⁻³.

The temperature of the second heat treatment performed in an atmosphere containing at least one element selected from the group consisting of hydrogen (H), deuterium (D), and fluorine (F) is preferably equal to or more than 400° C. and equal to or less than 900° C., more preferably equal to or more than 550° C. and equal to or less than 850° C., and even more preferably equal to or more than 700° C. and equal to or less than 800° C. By exceeding the above lower limit, the number of dangling bonds of silicon is reduced. In addition, by falling below the above upper limit, the second heat treatment becomes easier.

When forming a MOSFET using silicon carbide, there is a problem that the mobility of carriers decreases or the threshold voltage fluctuates. In addition, there is a problem that the leakage current of the gate insulating layer increases and the reliability of the gate insulating layer decreases. One factor that causes the above-described problems is thought to be nitrogen defects or carbon defects in the gate insulating layer.

Defects in the gate insulating layer are thought to be factors that cause the above-described problems by forming trap levels in the gate insulating layer.

In the semiconductor device manufacturing method according to the second embodiment, a silicon-rich silicon oxide film is formed (step S205). Even if the silicon carbide layer 10 is oxidized to form C—O—N bonds by the first heat treatment (step S207) performed in an atmosphere containing nitrogen oxide gas (NOx), carbon or nitrogen in the silicon site is substituted by the excess silicon contained in the silicon oxide film.

The substituted carbon is removed from the silicon oxide film as carbon monoxide gas. In addition, the substituted nitrogen is removed from the silicon oxide film as nitrogen gas. For this reason, C—O—N bonds are removed from the silicon oxide film. Therefore, C—O—N bonds are prevented from finally remaining in the gate insulating layer. As a result, according to the semiconductor device manufacturing method according to the second embodiment, the MOSFET 200 is realized in which a decrease in carrier mobility, a decrease in threshold voltage, a fluctuation in threshold voltage, an increase in the leakage current of the gate insulating layer, or a decrease in the reliability of the gate insulating layer due to defects in the gate insulating layer 28 is suppressed.

From the viewpoint of increasing excess silicon and removing C—O—N bonds from the silicon oxide film, the atomic concentration of oxygen (O) contained in the silicon oxide film is preferably equal to or less than 1.99 times the atomic concentration of silicon (Si), more preferably equal to or less than 1.95 times the atomic concentration of silicon (Si).

From the viewpoint of facilitating the formation of a silicon oxide film, the atomic concentration of oxygen (O) contained in the silicon oxide film is preferably equal to or more than 1.9 times the atomic concentration of silicon (Si).

The temperature of the first heat treatment performed in an atmosphere containing nitrogen oxide gas (NOx) is preferably equal to or more than 900° C. and equal to or less than 1250° C., more preferably equal to or more than 925° C. and equal to or less than 1100° C., and even more preferably equal to or more than 950° C. and equal to or less than 1000° C. By exceeding the above lower limit, strain in the silicon oxide film is reduced. In addition, by falling below the above upper limit, oxidation of the silicon carbide layer is suppressed.

In the semiconductor device manufacturing method according to the second embodiment, it is preferable not to perform heat treatment at a temperature exceeding the temperature of the first heat treatment in an atmosphere containing nitrogen before the first heat treatment after forming the silicon oxide film. For example, in order to suppress the oxidation of the silicon carbide layer, heat treatment for terminating dangling bonds on the surface with nitrogen may be performed in an oxygen-free atmosphere. As described above, in the semiconductor device manufacturing method according to the second embodiment, defects in the gate insulating layer 28 can be suppressed even when the silicon carbide layer is oxidized. Therefore, additional heat treatment in an atmosphere containing nitrogen does not need to be performed before the first heat treatment. Since heat treatment in an atmosphere containing nitrogen is not performed before the first heat treatment after forming the silicon oxide film, the semiconductor device manufacturing method can be simplified.

When a silicon film containing boron (B) is used as a material for the gate electrode 30 of a MOSFET, for example, boron (B) may be diffused into the gate insulating layer 28 and diffused into the silicon carbide layer 10 during heat treatment to activate boron (B). When boron (B) is diffused into the silicon carbide layer 10, the threshold voltage of the MOSFET fluctuates.

In the semiconductor device manufacturing method according to the second embodiment, the diffusion prevention region 42 containing nitrogen is formed by the first heat treatment (step S207) performed in an atmosphere containing nitrogen oxide gas (NOx). The diffusion prevention region 42 suppresses the diffusion of boron (B). Therefore, a fluctuation in the threshold voltage of the MOSFET 200 is suppressed.

If the diffusion prevention region 42 containing nitrogen is provided between the gate insulating layer 28 and the gate electrode 30 of the MOSFET, fixed charges may be formed due to the interface state of the diffusion prevention region 42. If fixed charges are formed between the gate insulating layer 28 and the gate electrode 30, the threshold voltage of the MOSFET may fluctuate.

In the semiconductor device manufacturing method according to the second embodiment, the second heat treatment (step S208) is performed in an atmosphere containing at least one element selected from the group consisting of hydrogen (H), deuterium (D), and fluorine (F). By the second heat treatment, the at least one element is segregated in the diffusion prevention region 42. In the diffusion prevention region 42, the at least one element reduces the interface state of the diffusion prevention region 42. Therefore, the formation of fixed charges in the diffusion prevention region 42 is suppressed. As a result, the MOSFET 200 is realized in which a fluctuation in threshold voltage is suppressed.

From the viewpoint of suppressing a fluctuation in threshold voltage, the atomic concentration of the at least one element at the fourth peak of the concentration distribution of the at least one element in the diffusion prevention region 42 is preferably equal to or more than 1×10¹⁷ cm⁻³, more preferably equal to or more than 1×10¹⁸ cm⁻³, and even more preferably equal to or more than 1×10¹⁹ cm⁻³.

The temperature of the second heat treatment performed in an atmosphere containing at least one element selected from the group consisting of hydrogen (H), deuterium (D), and fluorine (F) is preferably equal to or more than 400° C. and equal to or less than 900° C., more preferably equal to or more than 550° C. and equal to or less than 850° C., and even more preferably equal to or more than 700° C. and equal to or less than 800° C. By exceeding the above lower limit, the amount of fixed charges in the diffusion prevention region 42 is reduced. In addition, by falling below the above upper limit, the second heat treatment becomes easier.

In addition, the second heat treatment (step S208) performed in an atmosphere containing at least one element selected from the group consisting of hydrogen (H), deuterium (D), and fluorine (F) is preferably performed after the first heat treatment (step S207) is performed in an atmosphere containing nitrogen oxide gas (NOx). If the second heat treatment is performed before the first heat treatment, excess silicon in the silicon oxide film and the at least one element may be bonded to suppress the diffusion of the at least one element in the silicon oxide film.

From the viewpoint of suppressing a fluctuation in threshold voltage due to fixed charges, the atomic concentration of the at least one element at the peak of the concentration distribution of the at least one element in the diffusion prevention region 42 is preferably equal to or more than 1×10¹⁷ cm⁻³, more preferably equal to or more than 1×10¹⁸ cm⁻³, and even more preferably equal to or more than 1×10¹⁹ cm⁻³.

As described above, according to the second embodiment, a semiconductor device manufacturing method that reduces the amount of defects in the gate insulating layer is realized. In addition, according to the second embodiment, a semiconductor device manufacturing method is realized in which the diffusion of boron contained in the gate electrode is suppressed.

### Third Embodiment

A semiconductor device manufacturing method according to a third embodiment is different from the semiconductor device manufacturing method according to the second embodiment in that a trench is formed in a silicon carbide layer before forming a silicon oxide film. In addition, a semiconductor device according to the third embodiment is different from the semiconductor device according to the second embodiment in that the silicon carbide layer includes a trench.

Hereinafter, the description of a part of the content overlapping the first or second embodiment may be omitted.

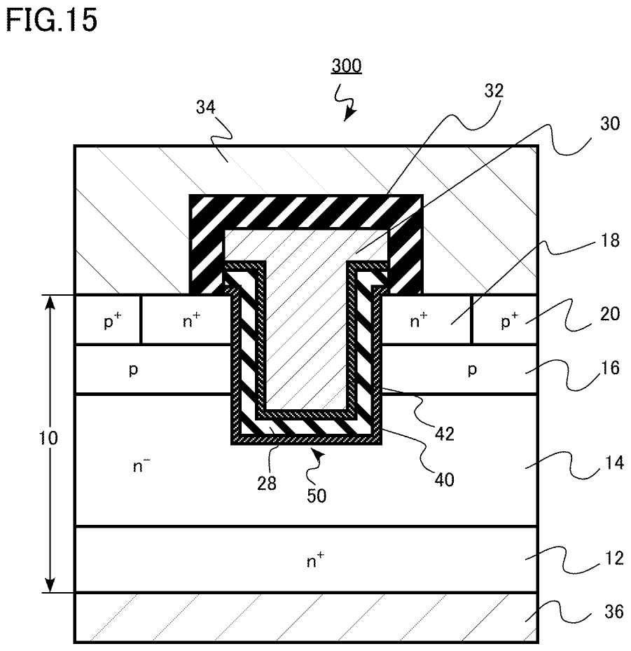

FIG. 15 is a schematic cross-sectional view of the semiconductor device according to the third embodiment. The semiconductor device is a MOSFET 300. The MOSFET 300 is a trench gate type MOSFET having a gate electrode in a trench. In addition, the MOSFET 300 is an n-channel MOSFET having electrons as carriers.

The MOSFET 300 includes a silicon carbide layer 10, a gate insulating layer 28 (silicon oxide layer), a gate electrode 30, an interlayer insulating film 32, a source electrode 34, a drain electrode 36, an interface termination region 40 (first region), and a diffusion prevention region 42 (second region).

The silicon carbide layer 10 includes a drain region 12, a drift region 14, a p-well region 16, a source region 18, a p-well contact region 20, and a trench 50.

The silicon carbide layer 10 is, for example, a single crystal of 4H—SiC. The silicon carbide layer 10 is disposed between the source electrode 34 and the drain electrode 36.

The surface of the silicon carbide layer 10 is a face inclined by an angle equal to or more than 0 degrees and equal to or less than 8 degrees with respect to the silicon face, and the back surface of the silicon carbide layer 10 is a face inclined by an angle equal to or more than 0 degrees and equal to or less than 8 degrees with respect to the carbon face. The surface of the silicon carbide layer 10 has an off angle equal to or more than 0 degrees and equal to or less than 8 degrees with respect to the silicon face.

The trench 50 passes through the source region 18 and the p-well region 16 and reaches the drift region 14. The bottom surface of the trench 50 is disposed in the drift region 14. The trench 50 is a groove provided in the silicon carbide layer 10.

The face orientation of the inner surface of the trench 50 is, for example, a face inclined by an angle equal to or more than 0 degrees and equal to or less than 8 degrees with respect to the m-face. In other words, the face orientation of the inner surface of the trench 50 is, for example, a face inclined by an angle equal to or more than 0 degrees and equal to or less than 8 degrees with respect to the {1-100}face.

The face orientation of the inner surface of the trench 50 is, for example, a face inclined by an angle equal to or more than 0 degrees and equal to or less than 8 degrees with respect to the a-face. In other words, the face orientation of the inner surface of the trench 50 is, for example, a face inclined by an angle equal to or more than 0 degrees and equal to or less than 8 degrees with respect to the {11-20}face.

The gate insulating layer 28 is provided in the trench 50.

The interface termination region 40 is disposed between the silicon carbide layer 10 and the gate insulating layer 28. The interface termination region 40 is disposed between the drift region 14 and the p-well region 16 and the gate insulating layer 28.

The interface termination region 40 contains nitrogen (N) as a termination element for terminating the dangling bond of the silicon carbide layer 10. Nitrogen (N) terminates dangling bonds of silicon in the silicon carbide layer 10, for example.

In addition, the interface termination region 40 contains at least one element selected from a group consisting of hydrogen (H), deuterium (D), and fluorine (F) as a termination element for terminating dangling bonds in the silicon carbide layer 10. The at least one element described above terminates dangling bonds of carbon in the silicon carbide layer 10, for example.

The atomic concentration of at least one element selected from the group consisting of hydrogen (H), deuterium (D), and fluorine (F) in the interface termination region 40 is lower than the atomic concentration of nitrogen (N) in the interface termination region 40, for example. The atomic concentration of at least one element selected from the group consisting of hydrogen (H), deuterium (D), and fluorine (F) in the interface termination region 40 is, for example, equal to or more than 1/10000 and equal to or less than 1/10 of the atomic concentration of nitrogen (N) in the interface termination region 40.

The diffusion prevention region 42 is disposed between gate insulating layer 28 and gate electrode 30.

The diffusion prevention region 42 contains nitrogen (N). The diffusion prevention region 42 contains, for example, oxygen (O). The diffusion prevention region 42 contains, for example, silicon oxynitride. The diffusion prevention region 42 has a function of preventing boron (B) contained in the gate electrode 30 from diffusing into the gate insulating layer 28 or the silicon carbide layer 10.

In addition, the diffusion prevention region 42 contains at least one element selected from the group consisting of hydrogen (H), deuterium (D), and fluorine (F). The at least one element in the diffusion prevention region 42 has a function of suppressing the generation of fixed charges at the interface between the gate insulating layer 28 and the gate electrode 30, for example.

The atomic concentration of at least one element selected from the group consisting of hydrogen (H), deuterium (D), and fluorine (F) in the diffusion prevention region 42 is lower than the atomic concentration of nitrogen (N) in the diffusion prevention region 42, for example. The atomic concentration of at least one element selected from the group consisting of hydrogen (H), deuterium (D), and fluorine (F) in the diffusion prevention region 42 is, for example, equal to or more than 1/10000 and equal to or less than 1/10 of the atomic concentration of nitrogen (N) in the diffusion prevention region 42.

Hereinafter, a case where the above-described at least one element is fluorine (F) will be described as an example.

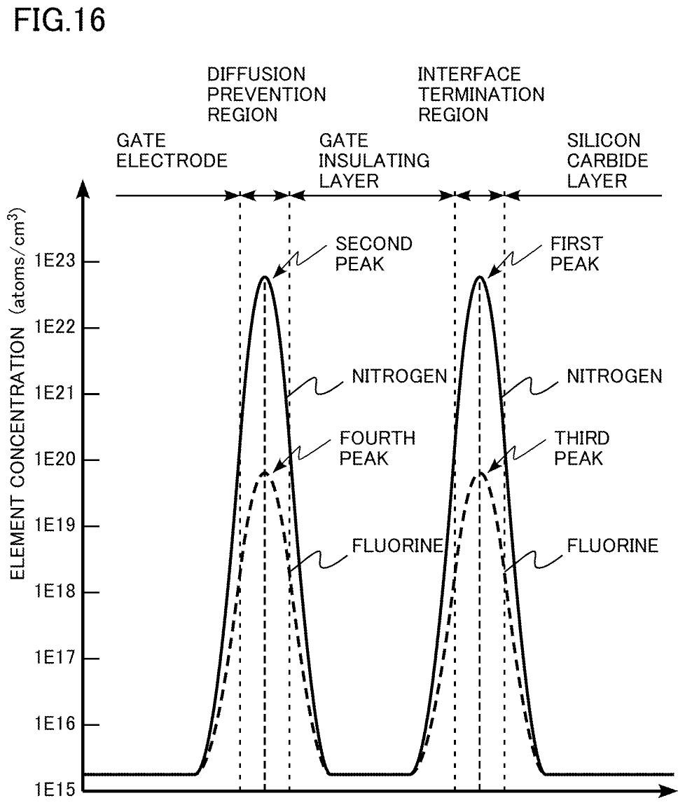

FIG. 16 is a diagram showing an example of the element concentration distribution of the semiconductor device according to the third embodiment. FIG. 16 is a diagram showing the element concentration distribution in the gate electrode 30, the diffusion prevention region 42, the gate insulating layer 28, the interface termination region 40, and the silicon carbide layer 10. FIG. 16 shows the concentration distribution of nitrogen (N) and fluorine (F).

The concentration distribution of nitrogen (N) has a first peak in the interface termination region 40. The atomic concentration of nitrogen at the first peak is, for example, equal to or more than 1×10²¹ cm⁻³ and equal to or less than 1×10²³ cm⁻³. The full width at half maximum with respect to the first peak of the nitrogen concentration distribution is, for example, equal to or less than 1 nm. Nitrogen is segregated at the interface between the silicon carbide layer 10 and the gate insulating layer 28.

The concentration distribution of nitrogen (N) has a second peak in the diffusion prevention region 42. The atomic concentration of nitrogen at the second peak is, for example, equal to or more than 1×10²¹ cm⁻³ and equal to or less than 1×10²³ cm⁻³. The full width at half maximum with respect to the second peak of the nitrogen concentration distribution is, for example, equal to or less than 1 nm. Nitrogen is segregated at the interface between the gate insulating layer 28 and the gate electrode 30.

The concentration distribution of fluorine (F) has a third peak in the interface termination region 40. The atomic concentration of fluorine at the third peak is, for example, equal to or more than 1×10¹⁷ cm⁻³ and equal to or less than 1×10²¹ cm⁻³. The full width at half maximum with respect to the third peak of the fluorine concentration distribution is, for example, equal to or less than 1 nm. Fluorine is segregated at the interface between the silicon carbide layer 10 and the gate insulating layer 28.

Fluorine terminates dangling bonds of carbon, for example. In the interface termination region 40, the amount of fluorine bonded to carbon is larger than the amount of fluorine bonded to silicon. In the interface termination region 40, the concentration of fluorine bonded to carbon is higher than the concentration of fluorine bonded to silicon.

The concentration distribution of fluorine (F) has a fourth peak in the diffusion prevention region 42. The atomic concentration of fluorine at the fourth peak is, for example, equal to or more than 1×10¹⁷ cm⁻³ and equal to or less than 1×10²¹ cm⁻³. The full width at half maximum with respect to the fourth peak of the fluorine concentration distribution is, for example, equal to or less than 1 nm. Fluorine is segregated at the interface between the gate insulating layer 28 and the gate electrode 30.

The gate electrode 30 is provided in the trench 50. The gate electrode 30 contains polycrystalline silicon containing boron (B). The gate electrode 30 is, for example, a polycrystalline silicon layer containing boron (B). The gate electrode 30 may have a stacked structure of a polycrystalline silicon layer containing boron (B) and a metal layer.

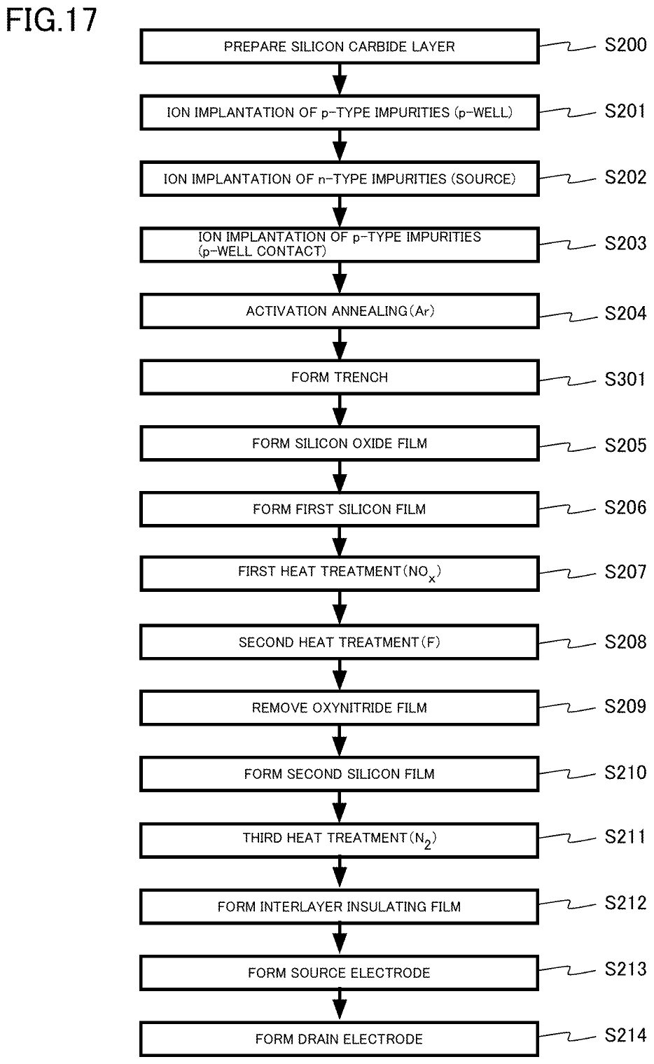

FIG. 17 is a process flow diagram of the semiconductor device manufacturing method according to the third embodiment.

As shown in FIG. 17, the semiconductor device manufacturing method according to the third embodiment includes preparation of a silicon carbide layer (step S200), ion implantation of p-type impurities (step S201), ion implantation of n-type impurities (step S202), ion implantation of p-type impurities (step S203), activation annealing (step S204), formation of a trench (step S301), formation of a silicon oxide film (step S205), formation of a first silicon film (step S206), first heat treatment (step S207), second heat treatment (step S208), removal of an oxynitride film (step S209), formation of a second silicon film (step S210), third heat treatment (step S211), formation of an interlayer insulating film (step S212), formation of a source electrode (step S213), and formation of a drain electrode (step S214). The semiconductor device manufacturing method according to the third embodiment is similar to the semiconductor device manufacturing method according to the second embodiment except for the formation of a trench (step S301).

In step S204, after activation annealing is performed, the carbon film on the surface of the silicon carbide layer 10 is removed.

In step S301, the trench 50 is formed in the silicon carbide layer 10. The trench 50 is formed by using, for example, known photolithography and reactive ion etching methods (RIE method).

In step S205, the silicon oxide film 61 is formed on the silicon carbide layer 10. The silicon oxide film 61 is formed on the inner surface of the trench 50.

Next, the function and effect of the semiconductor device manufacturing method and the semiconductor device according to the third embodiment will be described.

The MOSFET 300 manufactured by the manufacturing method according to the third embodiment includes the interface termination region 40 with a high atomic concentration of nitrogen, similar to the MOSFET 200 manufactured by the manufacturing method according to the second embodiment. The interface termination region 40 is formed by the first heat treatment (step S207) performed in an atmosphere containing nitrogen oxide gas (NOx). Therefore, through the manufacturing method according to the third embodiment, the MOSFET 300 is realized in which a decrease in carrier mobility is suppressed.

In addition, in the MOSFET 300 manufactured by the manufacturing method according to the third embodiment, the amount of defects in the gate insulating layer 28 is reduced, similar to the MOSFET 200 manufactured by the manufacturing method according to the second embodiment. The amount of defects in the gate insulating layer 28 is reduced by the formation of a silicon-rich silicon oxide film (step S205) and the first heat treatment (step S207) performed in an atmosphere containing nitrogen oxide gas (NOx). Therefore, by the manufacturing method according to the third embodiment, the MOSFET 300 is realized in which a decrease in carrier mobility, a decrease in threshold voltage, a fluctuation in threshold voltage, an increase in the leakage current of the gate insulating layer, or a decrease in the reliability of the gate insulating layer due to defects in the gate insulating layer 28 is suppressed.

In addition, the MOSFET 300 manufactured by the manufacturing method according to the third embodiment includes the diffusion prevention region 42 with a high atomic concentration of nitrogen, similar to the MOSFET 200 manufactured by the manufacturing method according to the second embodiment. The diffusion prevention region 42 is formed by the first heat treatment (step S207) performed in an atmosphere containing nitrogen oxide gas (NOx). Therefore, since the diffusion of boron (B) contained in the gate electrode 30 is suppressed by the manufacturing method according to the third embodiment, the MOSFET 300 is realized in which a fluctuation in threshold voltage is suppressed.

In addition, the MOSFET 300 manufactured by the manufacturing method according to the third embodiment includes the diffusion prevention region 42 with a high atomic concentration of at least one element selected from the group consisting of hydrogen (H), deuterium (D), and fluorine (F), similar to the MOSFET 200 manufactured by the manufacturing method according to the second embodiment. The diffusion prevention region 42 is formed by the first heat treatment (step S207) performed in an atmosphere containing nitrogen oxide gas (NOx). Therefore, since the generation of fixed charges is suppressed by the manufacturing method according to the third embodiment, the MOSFET 300 is realized in which a fluctuation in threshold voltage is suppressed.

When forming a MOSFET with a trench gate structure using silicon carbide, there is a problem that a fluctuation in threshold voltage occurs due to AC stress. One factor is thought to be the interface state between the silicon carbide layer and the gate insulating layer. It is thought that the interface state is caused particularly by dangling bonds of carbon on the surface of the silicon carbide layer.

In the semiconductor device manufacturing method according to the third embodiment, after the first heat treatment (step S207) is performed in an atmosphere containing nitrogen oxide gas (NOx), the second heat treatment (step S208) is performed in an atmosphere containing at least one element selected from the group consisting of hydrogen (H), deuterium (D), and fluorine (F). By performing the second heat treatment, in the interface termination region 40, at least one element selected from the group consisting of hydrogen (H), deuterium (D), and fluorine (F) terminates the dangling bonds of carbon in the silicon carbide layer 10. Therefore, since the number of dangling bonds of carbon on the surface of the silicon carbide layer is reduced, the MOSFET 300 is realized in which a fluctuation in threshold voltage due to AC stress is suppressed.

The temperature of the second heat treatment performed in an atmosphere containing at least one element selected from the group consisting of hydrogen (H), deuterium (D), and fluorine (F) is preferably equal to or more than 400° C. and equal to or less than 900° C., more preferably equal to or more than 550° C. and equal to or less than 850° C., and even more preferably equal to or more than 700° C. and equal to or less than 800° C. By exceeding the above lower limit, the number of dangling bonds of carbon is reduced. In addition, by falling below the above upper limit, the second heat treatment becomes easier.

In addition, the second heat treatment (step S208) performed in an atmosphere containing at least one element selected from the group consisting of hydrogen (H), deuterium (D), and fluorine (F) is preferably performed after the first heat treatment (step S207) is performed in an atmosphere containing nitrogen oxide gas (NOx). If the second heat treatment is performed before the first heat treatment, excess silicon in the silicon oxide film and the at least one element may be bonded to suppress the diffusion of the at least one element in the silicon oxide film.

In the MOSFET 300 according to the third embodiment, for example, a threshold voltage fluctuation when AC stress of 1 MHz from −5 MV/cm to 5 MV/cm is applied for 100 hours between the silicon carbide layer 10 and the gate electrode 30 is less than 0.1 V. Therefore, the MOSFET 300 has excellent AC stress tolerance.

From the viewpoint of suppressing a fluctuation in threshold voltage due to AC stress, it is preferable that in the interface termination region 40, the amount of the at least one element bonded to carbon (C) is larger than the amount of the at least one element bonded to silicon (Si).

From the viewpoint of suppressing a fluctuation in threshold voltage due to AC stress, the atomic concentration of the at least one element at the peak of the concentration distribution of the at least one element in the interface termination region 40 is preferably equal to or more than 1×10¹⁷ cm⁻³, more preferably equal to or more than 1×10¹⁸ cm⁻³, and even more preferably equal to or more than 1×10¹⁹ cm⁻³.

As described above, according to the third embodiment, a semiconductor device manufacturing method that reduces the amount of defects in the gate insulating layer is realized. In addition, according to the third embodiment, a semiconductor device manufacturing method is realized in which the diffusion of boron contained in the gate electrode is suppressed. In addition, according to the third embodiment, a semiconductor device with excellent AC stress tolerance is realized.

As described above, in the first to third embodiments, the case of 4H—SiC has been described as an example of the crystal structure of silicon carbide. However, embodiments can also be applied to silicon carbide having other crystal structures, such as 6H—SiC and 3C—SiC.

In addition, in the first to third embodiments, the method of manufacturing an n-channel MOSFET has been described as an example. However, embodiments can also be applied to a method of manufacturing an n-channel insulated gate bipolar transistor (IGBT).

While certain embodiments have been described, these embodiments have been presented by way of example only, and are not intended to limit the scope of the inventions. Indeed, the semiconductor device manufacturing method and the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device manufacturing method, comprising:
forming a trench in a silicon carbide layer, the silicon carbide layer having a surface inclined by an angle equal to or more than 0 degrees and equal to or less than 8 degrees with respect to a {0001}face;
forming a silicon oxide film on an inner surface of the trench, an atomic concentration of oxygen (O) in the silicon oxide film being less than twice an atomic concentration of silicon (Si) in the silicon oxide film;
performing a first heat treatment in an atmosphere containing nitrogen oxide gas after the forming the silicon oxide film;
performing a second heat treatment in an atmosphere containing at least one element selected from a group consisting of hydrogen (H), deuterium (D), and fluorine (F) after the first heat treatment; and
forming a gate electrode on the silicon oxide film after the second heat treatment.

2. The semiconductor device manufacturing method according to claim 1,
wherein the atomic concentration of oxygen (O) in the silicon oxide film is equal to or less than 1.99 times the atomic concentration of silicon (Si).

3. The semiconductor device manufacturing method according to claim 1,
wherein a temperature of the first heat treatment is equal to or more than 900° C. and equal to or less than 1250° C.

4. The semiconductor device manufacturing method according to claim 1,
wherein a temperature of the second heat treatment is equal to or more than 400° C. and equal to or less than 900° C.

5. The semiconductor device manufacturing method according to claim 1,
wherein the silicon oxide film is formed by using a vapor deposition method.

6. The semiconductor device manufacturing method according to claim 1,
wherein heat treatment in an atmosphere containing nitrogen is not performed before the first heat treatment after the forming the silicon oxide film.

7. A semiconductor device manufacturing method, comprising:
forming a silicon oxide film on a silicon carbide layer, an atomic concentration of oxygen (O) in the silicon oxide film being less than twice an atomic concentration of silicon (Si) in the silicon oxide film;
forming a first silicon film on the silicon oxide film;
performing a first heat treatment in an atmosphere containing nitrogen oxide gas after the forming the first silicon film; and
forming a second silicon film containing boron (B) and thicker than the first silicon film after the first heat treatment.

8. The semiconductor device manufacturing method according to claim 7,
wherein, before the forming the silicon oxide film, a trench is formed in the silicon carbide layer, a surface of the silicon carbide layer is inclined by an angle equal to or more than 0 degrees and equal to or less than 8 degrees with respect to a {0001}face, and
the silicon oxide film is formed on an inner surface of the trench.

9. The semiconductor device manufacturing method according to claim 7,
wherein the atomic concentration of oxygen (O) in the silicon oxide film is equal to or less than 1.99 times the atomic concentration of silicon (Si).

10. The semiconductor device manufacturing method according to claim 7,
wherein a temperature of the first heat treatment is equal to or more than 900° C. and equal to or less than 1250° C.

11. The semiconductor device manufacturing method according to claim 7,
wherein the first silicon film and the second silicon film are polycrystalline silicon.

12. The semiconductor device manufacturing method according to claim 7,
wherein the first silicon film contains or does not contain boron (B), and
an atomic concentration of boron (B) contained in the first silicon film is lower than an atomic concentration of boron (B) contained in the second silicon film.

13. The semiconductor device manufacturing method according to claim 7 further comprising:
performing a second heat treatment after the first heat treatment, in an atmosphere containing at least one element selected from a group consisting of hydrogen (H), deuterium (D), and fluorine (F).

14. The semiconductor device manufacturing method according to claim 7 further comprising:
removing a film containing oxygen (O) and nitrogen (N) formed on the first silicon film before the forming the second silicon film after the first heat treatment.

15. The semiconductor device manufacturing method according to claim 7,
wherein the silicon oxide film is formed by using a vapor deposition method.

16. A semiconductor device, comprising:
a silicon carbide layer having a surface inclined by an angle equal to or more than 0 degrees and equal to or less than 8 degrees with respect to a {0001}face and including a trench;
a gate electrode provided in the trench;
a silicon oxide layer provided between the silicon carbide layer and the gate electrode; and
a region provided between the silicon carbide layer and the silicon oxide layer and containing nitrogen (N) and at least one element selected from a group consisting of hydrogen (H), deuterium (D), and fluorine (F).

17. The semiconductor device according to claim 16,
wherein an atomic concentration of the at least one element in the region is lower than an atomic concentration of nitrogen in the region.

18. The semiconductor device according to claim 16,
wherein a concentration distribution of nitrogen in the silicon carbide layer, the silicon oxide layer, and the region has a peak in the region.

19. The semiconductor device according to claim 18,
wherein an atomic concentration of nitrogen at the peak is equal to or more than 1×10²¹ cm⁻³.

20. The semiconductor device according to claim 16,
wherein a concentration distribution of the at least one element in the silicon carbide layer, the silicon oxide layer, and the region has a peak in the region.

21. The semiconductor device according to claim 20,
wherein an atomic concentration of the at least one element at the peak is equal to or more than 1×10¹⁷ cm⁻³.

22. The semiconductor device according to claim 16,
wherein, in the region, an amount of the at least one element bonded to carbon (C) is larger than an amount of the at least one element bonded to silicon (Si).

23. The semiconductor device according to claim 16,
wherein a threshold voltage fluctuation when AC stress of 1 MHz from −5 MV/cm to 5 MV/cm is applied for 100 hours between the silicon carbide layer and the gate electrode is less than 0.1 V.

24. A semiconductor device, comprising:
a silicon carbide layer;
a gate electrode containing polycrystalline silicon containing boron (B);
a silicon oxide layer provided between the silicon carbide layer and the gate electrode;
a first region provided between the silicon carbide layer and the silicon oxide layer and containing nitrogen (N); and
a second region provided between the silicon oxide layer and the gate electrode and containing nitrogen (N).

25. The semiconductor device according to claim 24,
wherein the silicon carbide layer includes a trench,
a surface of the silicon carbide layer is inclined by an angle equal to or more than 0 degrees and equal to or less than 8 degrees with respect to a {0001}face, and
the gate electrode is provided in the trench.

26. The semiconductor device according to claim 24,
wherein a concentration distribution of nitrogen in the silicon carbide layer, the first region, the silicon oxide layer, the second region, and the gate electrode has a first peak in the first region and a second peak in the second region.

27. The semiconductor device according to claim 26,
wherein an atomic concentration of nitrogen at the first peak and an atomic concentration of nitrogen at the second peak are equal to or more than 1×10²¹ cm⁻³.

28. The semiconductor device according to claim 24,
wherein the first region contains at least one element selected from a group consisting of hydrogen (H), deuterium (D), and fluorine (F), and
the second region contains at least one element selected from the group consisting of hydrogen (H), deuterium (D), and fluorine (F).

29. The semiconductor device according to claim 28,
wherein a concentration distribution of nitrogen in the silicon carbide layer, the first region, the silicon oxide layer, the second region, and the gate electrode has a first peak in the first region and a second peak in the second region, and
a concentration distribution of the at least one element in the silicon carbide layer, the first region, the silicon oxide layer, the second region, and the gate electrode has a third peak in the first region and a fourth peak in the second region.

30. The semiconductor device according to claim 29,
wherein an atomic concentration of nitrogen at the first peak and an atomic concentration of nitrogen at the second peak are equal to or more than 1×10²¹ cm⁻³, and
an atomic concentration of the at least one element at the third peak and an atomic concentration of the at least one element at the fourth peak is equal to or more than 1×10¹⁷ cm⁻³.
